(19) United States
(12) Patent Application Publication
(10) Pub. No.: US 2024/0296617 A1
(43) Pub. Date: Sep. 5, 2024

(54) ACQUISITION OF POLARIMETRIC CHARACTERISTICS WITH IMPROVED COMPUTATIONAL EFFICIENCY

(71) Applicant: Arizona Board of Regents on Behalf of the University of Arizona, Tucson, AZ (US)

(72) Inventor: Meredith Kupinski, Tucson, AZ (US)

(21) Appl. No.: 18/572,521

(22) PCT Filed: May 3, 2022
(86) PCT No.: PCT/US2022/027492

§ 371 Date: Dec. 20, 2023

Related U.S. Application Data
(60) Provisional application No. 63/213,016, filed on Jun. 21, 2021.

(51) Int. Cl. G02B 27/28

(52) U.S. Cl. CPC G02B 27/286

(57) ABSTRACT

Methods, systems and devices for improving design, testing and characterization of scenes and optical systems for generating those scenes are described. The described methodology can be used, for example, to improve the generation and characterization of compute generated and virtual/augmented reality sciences by taking into consideration polarizing light-matter interactions. One example method includes an improved ray tracing technique with reduced computational needs that includes generating an incoming polarized ray and determining an exitant ray of the system using a probabilistic computation after interaction with the one or more depolarizing components. The generation of the exitant ray includes selecting a Jones matrix and the parameters of the incoming ray to compute a direction and a radiance of the exitant ray after interaction with a material that is at least partially depolarizing. These steps are repeated until a convergence criterion is reached.

### CROSS-REFERENCE TO RELATED APPLICATION(S)

This application claims priority to the provisional application with Ser. No. 63/213,016, titled “INCOHERENT ADDITION TO GENERALIZE DEPOLARIZATION IN LIGHT SCATTERING MODELS,” filed Jun. 21, 2021. The entire contents of the above noted provisional application are incorporated by reference as part of the disclosure of this document.

### TECHNICAL FIELD

The technology described in this patent document generally relates to optical systems and more specifically to methods and devices that account for changes in polarization due to light-matter interaction.

### BACKGROUND

Physics-based rendering (PBR) engines attempt to generate photorealistic images by modeling light-matter interaction in a physically plausible way. PBR has become the standard rendering method in animation, gaming, and computer graphic research. More recently, PBR engines have incorporated polarization into rendering algorithms. The appearance of specular and diffuse highlights, as well as the shape of an object, are improved by polarization-aware material-based models. As such, there is a need for improved techniques for analyzing and characterizing systems in which considerations of polarized light-matter interactions can lead to improved image or system performance qualities. These techniques can be particularly of interest for applications such as computer vision, atmospheric sciences and imaging, stray light analysis, and medicine.

### SUMMARY

The disclosed embodiments relate to methods, systems and devices for improving design, testing and characterization of scenes and optical systems for generating those scenes, including computer generated graphics and virtual/augmented reality systems, that use polarized or partially polarized rays. One aspect of the disclosed embodiment relates to a method for tracing rays of light in a system that includes one or more depolarizing components. The method includes generating an incoming polarized ray, wherein the incoming ray is characterized by parameters including a direction, a radiance, and a polarization state. The method further includes determining an exitant ray of the system using a probabilistic computation after interaction with the one or more depolarizing components, wherein each depolarizing component is characterized by four Jones matrices and four scalar numeric values associated with probabilities of the four Jones matrices. Determining the exitant ray includes selecting a Jones matrix from the four Jones matrices and using the selected Jones matrix and the parameters of the incoming ray to compute a direction and a radiance of the exitant ray after interaction with a material that is at least partially depolarizing. The method further incudes repeating the steps of generating an incoming ray and determining an exitant ray one or more times to produce one or more exitant rays until a convergence criterion is reached.

Among various feature and benefits, the disclosed technology reduces the computational needs for characterizing the scenes that involve light-matter interaction which can result in reduced cost and physical footprint of associated hardware and software. The features and benefits can be applied to ray tracing systems and methods, as well as characterization of partial-polarization of ghost images or stray light in optical systems.

### BRIEF DESCRIPTION OF THE DRAWINGS

FIG. 1 illustrates an example flow diagram of simulation and ray tracing operations that can be used for designing or analyzing an optical system in accordance with example embodiments of the disclosed technology.

FIG. 2 illustrates certain details of a light-matter interaction model used in accordance with an example embodiment.

FIG. 3 illustrates a plot of polarizance degree of linear polarization (DoLP) versus angle of incidence (AOI) for specular and diffuse models.

FIG. 4 illustrates plots of mean and standard deviation of the percent error between the true depolarizing Mueller matrix and the sample mean in accordance with an example embodiment.

FIG. 5 illustrates Mueller matrix measurements and computed metrics for an example pink silicone sphere.

FIG. 6 illustrates an example Rusinkiewicz coordinate system that can be used to define an acquisition geometry in accordance with an example embodiment.

FIG. 7 shows a listing of percentages of physical Mueller matrices for different material in the KAIST polarized bi-directional reflectance distribution function (pBRDF) database.

FIG. 8 illustrates example on-specular polarizance DoLP and a depolarization parameter versus AOIs associated with different materials.

FIG. 9 illustrates example rendered polarizance DOLP for specular reflection for an AOI of 30 degrees versus the number of samples per pixel.

FIG. 10 shows a listing of figures of merit to compare renderings from three different pBRDF databases.

FIG. 11 illustrates p example olarimetric renderings of RGB, polarizance angle of linear polarization (AoLP) and DoLP images of a pink silicone sphere for different databases.

FIG. 12 illustrates example polarimetric renderings of RGB, AoLP and DoLP images of a first scene for different databases.

FIG. 13 illustrates example polarimetric renderings of RGB, AoLP and DoLP images of a second scene for different databases.

FIG. 14 illustrates a set of operations that can be carried out to trace light rays in a system that includes one or more depolarizing components in accordance with an example embodiment.

FIG. 15 illustrates an example device that can be used as part of at least some of the disclosed embodiments.

### DETAILED DESCRIPTION

Models for polarized light scattering are of interest to a variety of technical fields including computer vision, atmospheric sciences, stray light analysis, medicine and others. For example, models for polarized light scattering are relevant for creating polarimetric-dependent virtual reality scenes. In a typical scenario, the polarimetry of objects is measured in the lab, fit to a model, and this model is used to simulate the polarized light scattering of objects in computer simulations and other applications. Typically, the models include polarized and unpolarized terms and measurements that are fit using traditional least-squares techniques. Notably, the two extreme conditions of light-matter interactions describe exitant light that is: 1) always unpolarized, irrespective of the polarization state of the incident light and 2) always polarized, irrespective of the polarization state of the incident light. A least-squares fit to a weighted sum of these two cases to characterize the light-matter interaction is attractive for its simplicity but insufficient for many applications. For example, the magnitude and structures of partial-polarization of the scattered light are required for models to generalize to diverse sets of materials, and even relatively simple variations in surface texture and albedo can defy the constraints of a single polarized bidirectional reflectance distribution function (p-BRDF) model. Model disagreement increases further when the geometric configurations of illumination and detection are varied.

Bidirectional reflectance distribution function (BRDF) is a function that defines how light is reflected at an opaque surface. It is employed in the modeling of real-world light, in computer graphics algorithms, and in computer vision algorithms, among other applications. BRDFs are scalar-valued functions that depend on the illumination and detection directions. Bidirectional scattering distribution function (BSDF) is a mathematical function which describes scattering of light from a surface and is sometimes considered as a superset of the BRDF and the bidirectional transmittance distribution function (BTDF), which correspond to the reflected and transmitted components of the scattered light, respectively. Polarized bi-directional scattering distribution functions (p-BSDF) are Mueller or Jones matrix-valued functions that also depend on the illumination and detection directions. In general, the various distribution functions can have two inputs (e.g., the angle of the incident light at a given point on a surface and the angle of output light-reflected or transmitted at that point on the surface depending on the function). The output of the function is the ratio between the incoming and the outgoing light energy for the given set of angles input to the function. The function can be a mathematical formula or model which attempts to approximate the actual surface behavior, and is often configured to produce the output based on discrete samples of measured data.

In recent years, research has led to a more nuanced understanding of polarized BSDF modeling for highly depolarizing surfaces. However, currently, optical path length (OPL)—associated with coherent ray tracing of polarized light—and depolarization effects produced due to light-matter interactions are not modeled together during ray tracing of scenes in computer graphics applications (e.g., augmented reality and virtual reality). If both are required, separate ray traces are needed: one for OPL using Jones calculus and one for depolarization using Mueller calculus. While polarization-aware rendering engines traditionally utilize analytic pBRDF Mueller matrix models, databases of measurements have recently been used for rendering applications. A Mueller matrix is a 4×4 real-valued matrix with 16 independent parameters. A pBRDF model has been proposed which uses a single depolarization parameter to quantify the relative weights between a completely depolarizing and a non-depolarizing Mueller matrix (e.g., Fresnel reflection or transmission).

The methods and systems according to the technology disclosed herein, among other features and benefits, allow improved design and testing of optical systems by simulating OPL and depolarization effects in a single ray trace. The disclosed techniques thus present significant improvements in, for example, the computer graphics technology as well as significant advancements in the field of computer-aided design of optical components and systems. One of the advantages of the disclosed embodiments is manifested in reduced computations needed for describing a partially-polarized graphical representation of a scene or the response of an optical system to unpolarized light because only a fully-polarized and an unpolarized computation of a given light-matter interaction is needed. In some embodiments, the fractional contribution of these two responses forms a single parameter which is part of the polarized BRDF of the material.

Accordingly, the disclosed techniques improve simulation, design and testing of coherent and incoherent systems. For instance, while in many coherent ray traces of optical systems (which consider OPL), depolarization effects are appropriate to neglect (e.g., lenses and mirrors are not depolarizing), scattering from non-optical surfaces (which are likely depolarizing) produces stray light that is at least partially depolarized. Thus, depolarizing light-matter interactions do not maintain fully-polarized states and the current Jones calculus used in coherent systems cannot account for such depolarizing interactions. The methods and systems of the disclosed embodiments address this problem, in-part, by employing an incoherent sum of coherent (i.e., fully-polarized) states to model depolarizing light-matter interactions, and use probabilistic methods to interpret coherent light-matter interactions. Computation of the incoherent sum of coherent states is performed in the methods according to the disclosed technology at the output of the ray trace procedure rather than at individual light-matter interactions.

Incoherent ray traces that do not require computation of OPL also benefit from computational advantages offered by the disclosed methods. Those advantages are achieved at least in-part through the use of the Jones calculus as opposed to Mueller calculus. Many rotation operations are required as light changes direction during a ray trace of a computer graphics scene or a model of an optical system. Mueller calculus is defined by a local coordinate system that changes with the direction of light travel. Jones vectors defined in global coordinates make these numerous rotation operations more computationally efficient. In particular, current state of the art incoherent ray traces which do not require OPL (e.g., illumination design, computer graphics rendering) use Mueller calculus to describe depolarizing light-matter interactions. In contrast, methods and systems according to the disclosed technology use parameterizations of polarized bi-directional distribution functions (e.g., the p-BSDF) which allows depolarizing light-matter interactions to be described via the Jones calculus as opposed to the Mueller one, thus resulting in significant computational savings.

As will be described in more detail herein, ray tracing operations based on probabilistic coherent distribution (e.g., p-BSDF) methods according to the disclosed technology are distinct from other approaches that use hypothetical ray paths to justify a diffuse term that is either completely or partially-depolarizing. For example, a probabilistic coherent p-BSDF model in accordance with the disclosed embodiments is a convex sum of up to four Jones matrices; this sum is equivalent to a Mueller matrix. For a given light-matter interaction, the weights of the convex sum are interpreted as probabilities and a single Jones matrix is sampled from the four Jones matrices based on those probabilities. For the probabilistic coherent p-BSDF model, each ray is fully-polarized and remains polarized through coherent light-matter interactions. At the output of the system, the rays are combined incoherently, and a completely general polarization state can be computed: partially-polarized, fully-polarized, or unpolarized.

Current state of the art describes only non-depolarizing materials with a Jones matrix valued p-BSDF. The methods according to the technology disclosed in this patent document describe depolarizing materials by a p-BSDF that is an ensemble (e.g., a weighted sum) of up to four Jones matrices each associated with a scalar value (e.g., a probability). A given light-matter interaction according to such an approach is coherent and, in general, an independent realization of the probabilistic selection will result in a different Jones matrix. These probabilities and ensemble of Jones matrices are the parameters of the depolarizing material's p-BSDF model used by the methods according to the disclosed technology.

As noted above, in current practice, light-matter interactions are computed using Mueller calculus for incoherent ray traces and Jones calculus for coherent ray traces. A Jones matrix methodology for depolarizing light-matter interactions according to the disclosed technology, implemented as an incoherent sum at the detector plane, bridges the gap between polarization-dependent wavefront aberration ray tracing in coherent ray traces and polarized light scattering from depolarizing surfaces in incoherent ray traces used in computer graphics. Light-matter interactions that can be described by a probabilistic coherent p-BRDF model according to the disclosed technology will have great computational advantages for incoherent ray traces. Coherent states, i.e., Jones matrices, can be described in a Pauli decomposition. Matrix-vector products and rotations of coordinate systems can then be computed using quaternion methods as opposed to linear algebra methods. Thus, a coherent probabilistic p-BRDF model according to the disclosed technology allows polarized ray traces for computer graphics to utilize quaternion computational advantages.

Another advantage offered by using incoherent addition of coherent states in the disclosed embodiments is an adjustable depolarization structure that maintains computational feasibility.

Before describing further details regarding the various embodiments, it is beneficial to note that the linear algebra of polarized light-matter interactions falls into one of two categories: Mueller calculus or Jones calculus. Mueller calculus describes fully polarized, partially polarized, and depolarized light, whereas Jones calculus only works with fully polarized light. Therefore, the fundamental difference between the two is depolarization. Incoherence can arise from either spatial, temporal, or spectral variations and introduces depolarization into measurements. For example, idealized monochromatic light from stimulated emission is always fully polarized because there is no source of incoherence and therefore Jones calculus is applicable. A Jones matrix is a 2×2 complex-valued matrix. A Jones matrix normalized by the complex-valued throughput has six degrees of freedom (DoF). These six DoF quantify diattenuation and retardance. In optical systems of lens and mirrors, the magnitude of depolarization is negligible. For these systems the diattenuation and retardance of wavefront aberrations are computed by incorporating Jones calculus into a ray trace.

A light-matter interaction which includes depolarization is described by a 4×4 real-valued Mueller matrix that can vary over wavelength, illumination direction, observation direction, and the surface normal. Given this 16-element matrix, seven of the sixteen degrees of freedom (DoF) are associated with non-depolarizing properties: retardance (3 DoF), diattenuation (3 DoF), and throughput (1 DoF). The other nine DoF are associated with depolarization. Every Mueller matrix is equal to a convex-sum of up to four Jones matrices. Thus, depolarization is mathematically expressed by the incoherent addition of coherent states. The four weights in this convex-sum are three of the nine DoF for depolarization. The sum of all these weights is equal to the throughput; therefore, only 3 depolarization DoF determine the four weights. The relative distribution of these four weights determines the magnitude of the depolarization index and a related metric, the entropy of the depolarization.

For a light-matter interaction with no depolarization, only one of the weights is non-zero. In this case the entropy is zero and the index of depolarization is one. The other extreme case is when all four weights are equally distributed. Now the index of depolarization is minimized to zero and the entropy is maximized to one. These four weights are computed from a linear transform that converts the Mueller matrix in a Hermitian form. The eigenvalues of this Hermitian matrix are the four weights. The singular-valued decomposition of a 4×4 Hermitian matrix can be expressed by 4 real-valued non-negative eigenvalues and a 4×4 unitary matrix where each row is an eigenvector. The remaining 6 DoF for depolarization are the angles which parameterize three of these eigenvectors. The eigenvector associated with the largest eigenvalue is determined from the retardance and diattenuation given by the 6 non-depolarizing DoF.

As noted earlier, p-BSDFs are Mueller matrix valued functions that depend on the illumination and detection directions, which describe how light is radiometrically reflected from a surface. The disclosed embodiments advantageously use incoherent addition of p-BSDF models and are distinct from other approaches that use hypothetical ray paths to justify a diffuse term that is either completely depolarizing or partially-polarizing. An incoherent addition p-BSDF model is a weighted sum of up to four Jones matrices.

Light-matter interactions that can be described by an incoherent addition of distribution functions (e.g., a p-BRDF or generally a p-BSDF model) will have great computational advantages. Coherent states, i.e., Jones matrices, can be described in a Pauli decomposition. Matrix-vector products and rotations of coordinate systems can then be computed in abstract algebra using quaternion methods as opposed to linear algebra methods. The computational benefits of quaternion methods in computer graphics are well-known. Compared to the current methods, the disclosed embodiments that use incoherent addition p-BRDF/p-BRSF models allow polarized ray traces for computer graphics to utilize these well-established quaternion computational advantages. A Jones matrix formalism, implemented as an incoherent sum of coherent states according to the disclosed technology, also bridges the gap between polarization-dependent wavefront aberration ray tracing in non-depolarizing systems and polarized light scattering from depolarizing surfaces.

The disclosed embodiments accommodate unpolarized, partially polarized, or fully polarized scattering through 4 fully polarized terms, wherein each term corresponds to a Jones matrix. Since these terms are fully polarized, least-squares fitting (e.g., weighted sums) of data associated with two extreme cases of fully polarized and unpolarized light is not needed. The Pauli spin coefficients of these 4 terms form an orthonormal set, and non-linear optimization in the fitting process can be replaced by matrix-vector multiplication.

In some embodiments, the weights in the incoherent sum can be computed from projections of the measured Mueller matrix (expressed in the Hermitian form) onto an orthonormal basis. This orthonormal basis projection offers a computational advantage compared to non-linear least-squares fitting. The increase in computational speed is because the orthonormal projection is closed-form as opposed to an iterative search. Also, a closed-form solution is not subject to the potential inaccuracies caused by local solutions. The orthonormal basis is parameterized by the 7 non-depolarizing DoF and the 6 angles of depolarization. Not all of these 13 DoF necessarily need to be fit to the measurements. Instead, prior information and physical models can inform some, or in special cases even all, of these 13 DoF. In backscattering configurations of diffuse materials, the 6 non-depolarizing DoF of retardance and diattenuation are usually characterized by Fresnel reflection. The dependence of Fresnel reflection on the geometric configuration of illumination and detection is well-known.

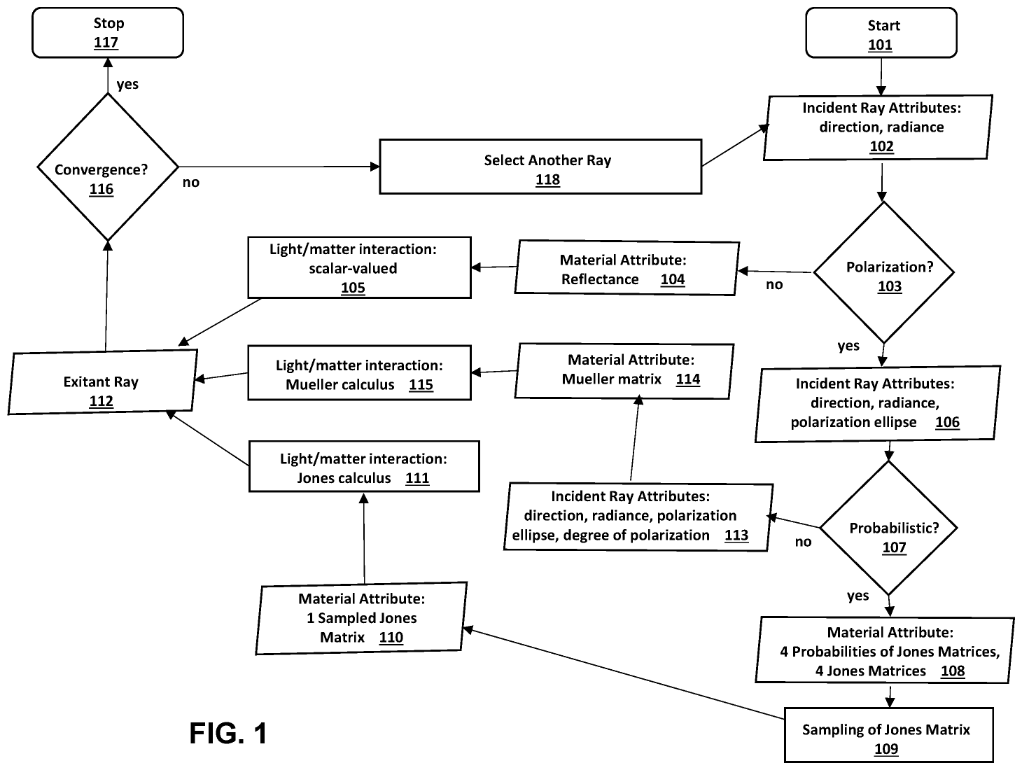

FIG. 1 illustrates an example flow diagram of simulation and ray tracing operations (“process”) that can be used for designing or analyzing an optical system in accordance with example embodiments of the disclosed technology. The operations begin at the box labeled as Start (101), followed by an operation (102) where an incident ray is generated and parameters of the incident ray such as its direction and radiance are specified. The method further includes deciding (at 103) if polarization of the incident ray should be taken into account. For example, a corresponding question and the related answer selection options can be provided in a user interface of a simulation software implementing the method. If, for example, a decision is made (e.g., by a user or in an automated fashion based on one or more selection criteria) that the simulation should proceed without taking the polarization state of the incident ray into account (“no”), then the process can proceed and use only scalar numeric values for description of material properties and light-matter interactions (e.g., reflectance) (104). The light-matter interaction, in this case, is determined (105) using the scalar-valued parameters. If, on the other hand, the polarization state of the incident ray needs to be taken into account (“yes” at 103), a polarization ellipse can be added to the parameters of the incident ray (e.g., an ellipse on the Poincare sphere) (106). Furthermore, in such a case, a decision can be made (not shown in FIG. 1) as to whether any depolarizing light-matter interactions should be included and if so, a determination is made (107) as to whether a probabilistic framework according to the technology disclosed in this patent document should be implemented or whether a non-probabilistic framework should be utilized.

If the process continues down the route of using the probabilistic framework according to the disclosed technology (“yes” at 107), then material properties of an object (e.g., in the virtual environment) are specified (108) using four Jones matrices and for probabilities associated with those Jones matrices, as described above. In the case of using the probabilistic framework, the process further includes, for each ray incident on the object, sampling a Jones matrix (109) from the four Jones matrices and using the selected Jones matrix (110) to compute (111), via Jones calculus, an exitant ray for the interaction of the incident ray with the object (112).

If a decision is made (or if the process is configured, e.g., in advance) to proceed via the non-probabilistic route of computing depolarizing light-matter interactions (“no” at 107), then a degree of polarization is added (113) into the parameters of the incident ray, a Mueller matrix is obtained (114) and the object with which the ray interacts is characterized using a Mueller matrix; Mueller calculus is then used to compute (115) an exitant ray (112) for a depolarizing interaction of the incident ray with the object. A determination is made (116) if there is convergence, and if so, the process stops (117). It should be noted that convergence is reached when certain criteria are satisfied. For example, in some embodiments, the number of rays per pixel can be set ahead of time, while in other embodiments additional rays are traced until the result substantially stops changing. Referring back to FIG. 1, if there is no convergence (no at 116), another ray is selected (118), and attributes for that ray are selected (102). It should be noted that the operations in FIG. 1 can be separated into three categories based on light-matter interaction models for ray tracing depolarizing material: (1) radiometric ray trace model (105), depolarizing Mueller matrix model (115) and light-matter interaction model based on probabilistic sampling of Jones matrix for importance sampling depolarization (111). It should be noted that in this patent document, the term importance sampling can be used to convey the general technique for estimating properties of a particular distribution, while only having samples generated from a different distribution than the distribution of interest.

Typically, propagation of multiple (e.g., thousands to millions) light rays in and/or through the virtual environment and interaction of those rays with various objects and/or surfaces in the environment is simulated in a ray trace simulation. A numeric criterion linked to a quality of the simulation result can be devised or provided. For example, such a criterion can be computed using one or more properties of the light rays that are output by the simulation. During the course of the simulation, convergence of such criterion to a target value can be tracked and the simulation can be stopped once the criterion is within a certain range from the target value.

To provide further insight as to the disclosed statistical approach, it is instructive to note that depolarization is often described as the result of physically averaging over disorder in a system, e.g., many scattered ray paths inside an integrating sphere. The disclosed statistical methodology advantageously treats the Mueller-Jones matrix (or Jones matrix) itself as a random variable in an otherwise deterministic process of polarization ray tracing. Then depolarization can be modeled as an expectation, or average-value, of the random Jones matrix in the ray trace. Performing an average over the ray trace result, given a Jones matrix for each light-matter interaction, allows for coherent states to be propagated through the ray trace and averaged at the detector plane. The conventional use of a depolarizing Mueller matrix to model light-matter interactions is equivalent to performing the ray trace instead on the average Mueller-Jones matrix. Further details and additional examples are described in Appendix which is at a later section in this patent document.

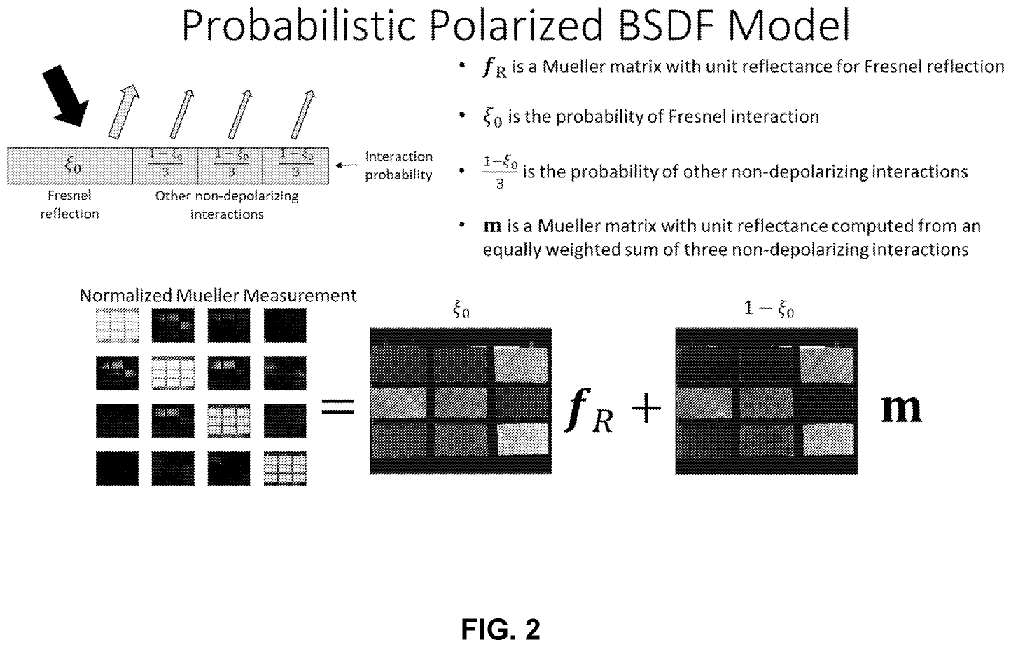

FIG. 2 illustrates certain details of a light-matter interaction model used in accordance with an example embodiment, wherein the model is based on a probabilistic approach that uses polarized bi-directional scattering distribution functions (p-BSDFs). As illustrated in FIG. 2, the major contributor is, ξ₀, the probability of interaction based on Fresnel reflection, and the three equally distributed probabilities for non-depolarizing interactions. A normalized Mueller matrix can be obtained from ξ₀ f_{R}+(1−ξ₀)m, wherein f_{R} is a Mueller matrix with unit reflectance for Fresnel reflection and m is a Mueller matrix with unit reflectance computed from an equally weighted sum of three non-depolarizing interactions.

According to the disclosed embodiments, the parameter representing the probability of Fresnel reflection can be obtained in different ways. For example, the probability can be obtained based on prior knowledge. Alternatively, the values can be determined based on a full measurement of Mueller matrix (e.g., goniometric measurements can be performed to measure the material's radiometric BRDF/BSDF). Another advantage of the methods according to the technology disclosed herein is that the p-BSDF model used by the disclosed methods lends itself to extrapolating a full characterization of the p-BSDF from a reduced set of measurements. In general, when characterizing a material, at minimum 16 measurements are required to measure the Mueller matrix. According to some embodiments, for certain depolarizing materials, less than 16 measurements, and as few as two measurements are sufficient to describe the probabilities.

As further shown by the example experiments and analysis provided in Appendix A, a Mueller matrix with a triply degenerate (TD) coherency eigenspectrum can be expressed using this single depolarization parameter pBRDF without loss of information. Instead of 16 parameters for a general Mueller matrix, the TD form has eight parameters: six for the normalized non-depolarizing Mueller matrix, a single depolarization parameter (e.g., the largest eigenvalue), and the unpolarized reflectance. Interpolating these eight TD parameters to unmeasured scattering geometries maintains a physically-realizable Mueller matrix. Using the TD form to represent a Mueller measurement compresses the data by a factor of two, as well as providing a physical constraint for interpolation. Rendering computations from the TD model offer a probabilistic interpretation. The depolarization parameter can be used to compute a probability for a given light-matter interaction. Then for each ray, a randomly generated selection is made between a non-depolarizing Mueller matrix or a completely depolarizing Mueller matrix. The rays are summed incoherently after the ray trace is completed. As further explained in the Appendix below, rendered polarimetric images using the TD model, and the TD model computed with polarimetric importance sampling, are compared to the original KAIST database.

Some of the advantages associated with the disclosed embodiments are as follows: an 8 parameter physically constrained model for 4×4 Mueller matrices can be produced which retains dominant polarimetric properties. The experiments conducted illustrate this for the 25 materials in the KAIST pBRDF database. Further, physical constraints when interpolated to non-measured geometries are provided, and convergence of the disclosed polarimetric importance (statistical) sampling methods are established.

As disclosed herein, one aspect of the disclosed embodiment relates to a single parameter depolarization pBRDF model that can be used to effectively characterize interaction of polarized light with matter. This model can be used to improve the computational efficiency of analyzing and designing optical systems that interact with polarized light. The signal depolarization parameter determines the fractional contribution of specular versus diffuse reflection. The depolarization parameter is the largest/unique eigenvalue in a triply degenerate (TD) assumption of the Cloude coherency eigenspectrum. This assumption can be used to compress the Mueller matrix database into a TD model database which is shown to retain dominant polarimetric properties for both diffuse and specular light-matter interactions. For each 4×4 Mueller matrix, the TD model consists of 8 parameters: the radiometric average throughput, the depolarization parameter, and 6 parameters to describe the dominant coherent process. These 8 TD parameters maintain physical constraints on the Mueller matrix when interpolated to unmeasured geometries. The TD model expression is a weighted sum of a normalized Mueller-Jones matrix and a completely depolarizing Mueller matrix. Polarimetric importance sampling is made possible by interpreting these weights as probabilities. Here, the depolarization parameter is used to determine the probability of a coherent/fully polarized or unpolarized light-matter interaction occurrence. In the disclosed embodiment, polarimetric measurements can be conducted to determine the fractional contribution of fully-polarized versus unpolarized light to characterize the depolarizing components or materials, and then use this characterization to simulate the materials' partially-polarized contribution in the ray trace.

The disclosed methodology was confirmed using a rendered pink silicone sphere from the KAIST pBRDF database, illustrating that the average deviation in the polarizance degree of linear polarization (DoLP) deviation was 1.1% for both the TD compressed and polarimetric importance sampled pBRDF model as compared to the uncompressed model, respectively. The deviation in the angle of linear polarization (AoLP) for this sphere was 16.9° for both the TD compressed and polarimetric importance sampled pBRDF model. The similar deviation achieved for both the TD compressed and polarimetric importance sampled pBRDF, confirms that polarimetric importance sampled pBRDF in accordance with the disclosed embodiments produces the same result as the conventional polarimetric ray trace technologies, albeit with significantly reduced computations. The polarimetric importance sampled pBRDF converged to the partially-depolarizing Mueller matrix pBRDF at 128 samples per pixel (spp). The pBRDF models are also compared by rendering two scenes containing multiple surface interactions and several material types. Polarimetric importance sampling convergence and its dependence on the materials' depolarization and ray depth are reported for these scenes.

An aspect of the disclosed technology relates to a method of tracing rays of light through a virtual environment that includes generating an incoming ray whose propagation needs to be traced through (or in) the environment, wherein the incoming ray is characterized by parameters including at least one of: a direction, a radiance, or a polarization state. The method further includes computing an exitant ray for an interaction of the incoming ray with an object or a surface (e.g., a surface of the object) in the environment, wherein the object is characterized by up to four Jones matrices associated with it and up to four scalar numeric values associated with the Jones matrices.

The interaction of the incoming ray with the object can be either depolarizing or non-depolarizing. When simulating a depolarizing interaction of the incoming ray with the object, the object can be associated with four Jones matrices as well as four scalar numeric values associated with these four Jones matrices. When simulating a non-depolarizing interaction of the incoming ray with the object, the object can be characterized by a single Jones matrix associated with it. In some implementations of the method, the computing the exitant ray includes selecting a matrix from the Jones matrices associated with the object and using the selected Jones matrix as well as the parameters of the incoming ray to compute, via Jones calculus, at least one of: a direction or a radiance of the exitant ray.

According to some example embodiments, each of the four scalar numeric values is associated with a matrix in the four Jones matrices that characterize an object in a depolarizing interaction of a light ray with the object and is a probability of selecting that particular Jones matrix out of the four Jones matrices associated with the object during computation of an exitant ray for the depolarizing interaction of the incoming ray with the object. In some example embodiments, a sum of these four probabilities is equal to 1 and the four probabilities describe the whole probability distribution for a process of selecting a matrix from the four Jones matrices.

A typical ray tracing simulation includes simulating propagation of multiple (e.g., millions) light rays through the virtual environment. For a depolarizing interaction of multiple incoming rays with a depolarizing surface or object in the environment, the above-mentioned probability distribution will determine an ensemble of exitant rays. The properties of this ensemble (e.g., a distribution of directions and/or radiances of the rays in it) will reflect the depolarizing effects of the surface or the object on the incoming rays. As mentioned above, these effects are typically computed using a single Mueller matrix associated with the object or the surface.

In some example embodiments, the four scalar numeric values associated with the four Jones matrices are obtained using a linear transform that converts a Mueller matrix associated with an object (or a surface of the object, or a configuration of one or more objects and/or surfaces) in a Hermitian form. According to certain example embodiments, the four scalar numeric values are eigenvalues of a Hermitian matrix, wherein the Hermitian matrix is a result of that linear transform.

A typical ray tracing simulation continues until a criterion to stop the simulation is satisfied. Such a criterion can be convergence of a certain measure computed using one or more output rays of the simulation to a certain target value. Once the target vale is reached, the simulation can be stopped.

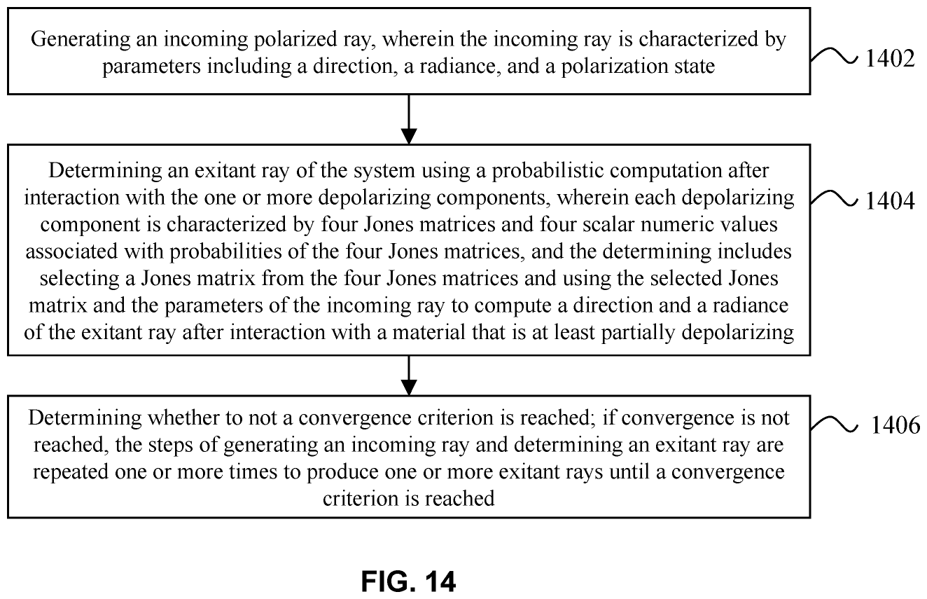

One aspect of the disclosed technology relates to a method, as shown in FIG. 14, for tracing rays of light in a system that includes one or more depolarizing components. At 1402, an incoming polarized ray is generated, wherein the incoming ray is characterized by parameters including a direction, a radiance, and a polarization state. At 1404, an exitant ray of the system is determined using a probabilistic computation after interaction with the one or more depolarizing components. Each depolarizing component is characterized by four Jones matrices and four scalar numeric values associated with probabilities of the four Jones matrices. The determination at 1402 includes selecting a Jones matrix from the four Jones matrices and using the selected Jones matrix and the parameters of the incoming ray to compute a direction and a radiance of the exitant ray after interaction with a material that is at least partially depolarizing. At 1404, a determination is made as to whether to not a convergence criterion is reached. If convergence is not reached, the steps of generating an incoming ray and determining an exitant ray are repeated one or more times to produce one or more exitant rays until a convergence criterion is reached.

In one example embodiment, the above noted method also includes performing one or more polarimetric measurements to obtain a fractional contribution of fully-polarized versus unpolarized light upon interaction with the one or more depolarizing components, and using the fractional contribution to determine a contribution associated with a partially-polarized light as part of the determining the exitant ray after interaction with the one or more depolarizing components. In another example embodiment, the selecting the Jones matrix is performed based on the four probability values. In yet another example embodiment, the convergence criterion includes one of: completion of tracing a predetermined number of rays, or upon reaching a condition where a characteristic of an exitant ray remains substantially unchanged compared to one or more previous exitant rays.

According to another example embodiment, the above noted method incudes obtaining the four scalar numeric values using a linear transform that converts a Mueller matrix associated with the one or more depolarizing components in a Hermitian form. In one example embodiment, the four scalar numeric values are eigenvalues of a Hermitian matrix, wherein the Hermitian matrix is a result of the linear transform.

In another example embodiment, the determining of the exitant ray includes using a single parameter depolarization probabilistic bidirectional reflectance distribution function (BRDF). In one example embodiment, the single parameter determines a fractional contribution of specular versus diffuse reflection. In another example embodiment, the single parameter is one of a largest or a unique eigenvalue in a triply degenerate (TD) coherency eigenspectrum. In yet another example embodiment, the above noted method includes compressing one or more Mueller matrices data associated with the one or more depolarizing components into a TD model database that retains dominant polarimetric properties for both diffuse and specular light-matter interactions. In still another example embodiment, wherein for each 4×4 Mueller matrix, the TD model database consists of 8 parameters that include a radiometric average throughput, a depolarization parameter, and 6 parameters that describe a dominant coherent process. According to another example embodiment, the single parameter is used to determine a probability of a fully polarized or unpolarized light-matter interaction occurrence.

Another aspect of the disclosed embodiments relates to a device for tracing rays of light in a system that includes one or more depolarizing components. The device includes a processor, and a memory including instructions stored thereon. The instructions upon execution by the processor causing the processor to generate an incoming polarized ray, wherein the incoming ray is characterized by parameters including a direction, a radiance, and a polarization state; and determine an exitant ray of the system using a probabilistic computation after interaction with the one or more depolarizing components. Each depolarizing component is characterized by four Jones matrices and four scalar numeric values associated with probabilities of the four Jones matrices. The determination of the exitant ray includes selecting a Jones matrix from the four Jones matrices and using the selected Jones matrix and the parameters of the incoming ray to compute a direction and a radiance of the exitant ray after interaction with a material that is at least partially depolarizing. The instructions upon execution by the processor cause the processor to repeat the steps of generating an incoming ray and determining an exitant ray one or more times to produce one or more exitant rays until a convergence criterion is reached.

In one example embodiment, the instructions upon execution by the processor cause the processor to determine a contribution associated with a partially-polarized light as part of the determination of the exitant ray based on a fractional contribution of fully-polarized versus unpolarized light upon interaction with the one or more depolarizing components that are obtained using one or more polarimetric measurements.

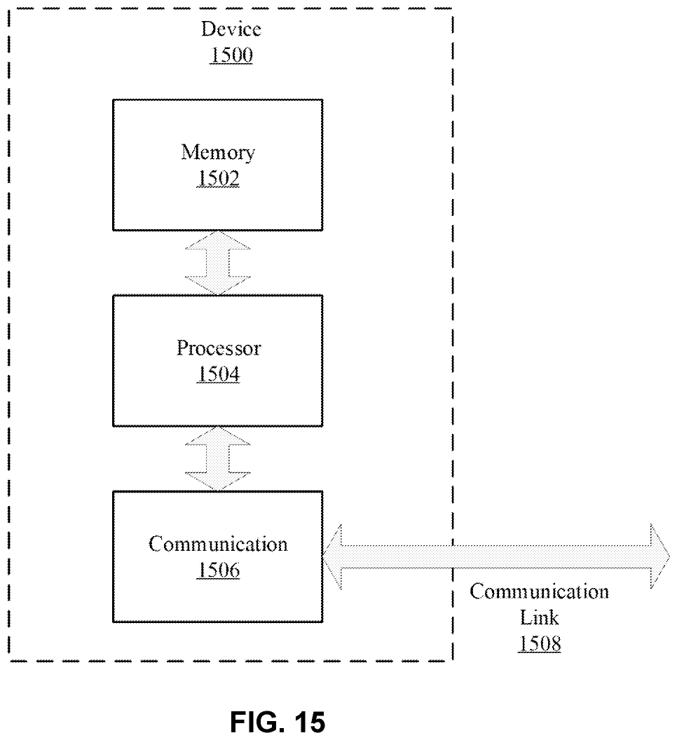

Another aspect of the technology disclosed in this patent document relates to a non-transient computer-readable storage medium including instructions that, when executed by a computer cause the computer to perform computations according to a method according to the technology disclosed in this patent document. In some example embodiments, the instructions cause the computer to perform a ray trace simulation that realizes a method according to the technology disclosed herein. According to some example embodiments, the computer includes one or more processors and a memory. In certain example embodiments, the non-transient computer-readable storage medium is a non-transient information storage device within the computer. According to some example embodiments, the computer further includes one or more graphics processing units (GPUs). In some example embodiments, the computer is a distributed computing system including one or more computing nodes. In certain example embodiments, at least some nodes of the computing system are communicatively linked to other nodes of the system via a communication network. According to some example embodiments, the communication network is a wired or wireless network. One example device that may be used to implement at least some of the disclosed embodiments is illustrated in FIG. 15. For example, the device 1500 of FIG. 15 can be used to receive, process, store, provide for display and/or transmit various data and signals associated with disclosed measurements and computations that are disclosed herein. The device 1500 comprises at least one processor 1504 and/or controller, at least one memory 1502 unit that is in communication with the processor 1504, and at least one communication unit 1506 that enables the exchange of data and information, directly or indirectly, through the communication link 1508 with other entities, devices, databases and networks. The communication unit 1506 may provide wired and/or wireless communication capabilities in accordance with one or more communication protocols, and therefore it may comprise the proper transmitter/receiver, antennas, circuitry and ports, as well as the encoding/decoding capabilities that may be necessary for proper transmission and/or reception of data and other information. The exemplary device 1500 of FIG. 15 may be integrated as part of larger component (e.g., a computer, tablet, smart phone, etc.).

While this patent document contains many specifics, these should not be construed as limitations on the scope of any invention or of what may be claimed, but rather as descriptions of features that may be specific to particular embodiments of particular inventions. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments.

It is understood that the various disclosed embodiments may be implemented individually, or collectively, using devices comprised of various optical components, electronics hardware and/or software modules and components. These devices, for example, may comprise a processor, a memory unit, an interface that are communicatively connected to each other, and may range from desktop and/or laptop computers, to mobile devices and the like. The processor and/or controller can perform various disclosed operations based on execution of program code that is stored on a storage medium. The processor and/or controller can, for example, be in communication with at least one memory and with at least one communication unit that enables the exchange of data and information, directly or indirectly, through the communication link with other entities, devices and networks. The communication unit may provide wired and/or wireless communication capabilities in accordance with one or more communication protocols, and therefore it may comprise the proper transmitter/receiver antennas, circuitry and ports, as well as the encoding/decoding capabilities that may be necessary for proper transmission and/or reception of data and other information. For example, the processor may be configured to receive electrical signals or information from the disclosed sensors (e.g., CMOS sensors), and to process the received information to produce images or other information of interest.

Various information and data processing operations described herein may be implemented in one embodiment by a computer program product, embodied in a computer-readable medium, including computer-executable instructions, such as program code, executed by computers in networked environments. A computer-readable medium may include removable and non-removable storage devices including, but not limited to, Read Only Memory (ROM), Random Access Memory (RAM), compact discs (CDs), digital versatile discs (DVD), etc. Therefore, the computer-readable media that is described in the present application comprises non-transitory storage media. Generally, program modules may include routines, programs, objects, components, data structures, etc. that perform particular tasks or implement particular abstract data types. Computer-executable instructions, associated data structures, and program modules represent examples of program code for executing steps of the methods disclosed herein. The particular sequence of such executable instructions or associated data structures represents examples of corresponding acts for implementing the functions described in such steps or processes

Only a few implementations and examples are described, and other implementations, enhancements and variations can be made based on what is described and illustrated in this patent document.

### APPENDIX

In this Appendix, various notations, definitions, and relationships for polarimetric parameters and quantities are described. These descriptions are provided to facilitate the understanding of the disclosed technology and establish their viability in conformance with scientific principles. These, along with example experimental results, confirm and corroborate the improvements achieved via implementations of the disclosed methods and devices that result in significant computational savings in designing optical systems that take into account depolarizing light-matter interaction in producing images and scenes with improved quality.

### Operational Definition of Mueller Matrices

The Mueller matrix provides the most general description of light-matter interaction in the absence of non-linear effects, and represents the polarization characteristics of an optical medium as determined by the relationship between a set of input polarization vectors and their corresponding output polarization vectors: Sₒᵤₜ=M. Sᵢₙ. For linear light-matter interactions, the polarimetric measurement equation relates the 4×4 Mueller matrix M to a scalar-valued intensity measurement

$$p = {a}^{†} Mg . \\ where M = [ \begin{matrix}{M}_{00} & {M}_{01} & {M}_{02} & {M}_{03} \\ {M}_{10} & {M}_{11} & {M}_{12} & {M}_{13} \\ {M}_{20} & {M}_{21} & {M}_{22} & {M}_{23} \\ {M}_{30} & {M}_{31} & {M}_{32} & {M}_{33}\end{matrix} ] . \qquad ( 1 )$$

In Equation (1), p is a noise-free measurement from a polarimeter, † denotes the transpose, a and g are 4×1 vectors of Stokes parameters describing the polarization state analyzer (PSA) and the polarization state generator (PSG), respectively. The PSG is the incident polarization state. The PSA is the polarization-sensitive transmission (e.g., diattenuation) of the optics between the light-matter interaction and the detector.

A radiometric (i.e., non-polarimetric) version of Eq. 1 sets the PSA/PSG to unpolarized states; g=a^{†}=[1,0,0,0]^{†}. The measurement of this unpolarized light-matter interaction is p=[M]₀₀=M₀₀ which is called the average throughput (i.e., reflectance or transmission). The leftmost column of the Mueller matrix is called the polarizance vector. This is the Stokes vector of exitant light when unpolarized light is incident. The top row of the Mueller matrix is called the diattenuation vector. This is the Stokes vector that forms an inner-product with the incident Stokes vector to compute the radiant exitance.

For a Stokes vector of the form S=[S₀,S₁,S₂,S₃] the degree of linear polarization (DoLP) is the ratio of the linearly polarized radiance to the total radiance (S₀)

$$DoLP = \frac{\sqrt{{S}_{1}^{2} + {S}_{2}^{2}}}{{S}_{0}} , \qquad ( 2 )$$

where a DoLP=0 is no linear polarization, and DoLP=1 is fully linearly polarized. The degree of polarization (DoP) includes elliptical states and S₃ is includes in the numerator of Eq. 2. Two parameters specify the polarization state when DoP=1

$$S ( θ , η ) / {S}_{0} = {[ \begin{matrix}1 & cos ( θ ) sin ( η ) & sin ( θ ) sin ( η ) & cos ( η )\end{matrix} ]}^{†} \qquad ( 3 )$$

where S₀ is the total radiance, θ and η are the latitude and longitude on the Poincare sphere, respectively.

A majority of analytic pBRDF models are weighted sums of Fresnel reflection and transmission Mueller matrices with microfacet and subsurface scattering terms. The DoLP of the polarizance vector for Fresnel reflection is

$${DoLP}_{s} ( {n}_{0} , {θ}_{o} ) = \frac{2 {sin}^{2} {θ}_{o} cos {θ}_{o} \sqrt{{n}_{0}^{2} - {sin}^{2} {θ}_{o}}}{{n}_{0}^{2} - {sin}^{2} {θ}_{o} - {n}_{0}^{2} {sin}^{2} {θ}_{o} + 2 {sin}^{4} {θ}_{o}} . \qquad ( 4 )$$

where the relative refractive index is n₀ and the viewing angle is θₒ. Fresnel reflection is defined only for specular acquisition geometries where θᵢ=θₒ. For Fresnel transmission the polarizance DoLP is

$${DoLP}_{d} ( {n}_{0} , {θ}_{o} ) = \frac{{( {n}_{0} - 1 / {n}_{0} )}^{2} {sin}^{2} {θ}_{o}}{2 + 2 {n}_{0}^{2} - {( {n}_{0} + 1 / {n}_{0} )}^{2} {sin}^{2} {θ}_{o} + 4 cos θ \sqrt{{n}_{0}^{2} - {sin}^{2} {θ}_{o}}} . \qquad ( 5 )$$

The polarizance DoLP of Fresnel transmission is used in pBRDF modelling for partially-polarized diffuse scattering and does not depend on illumination direction.

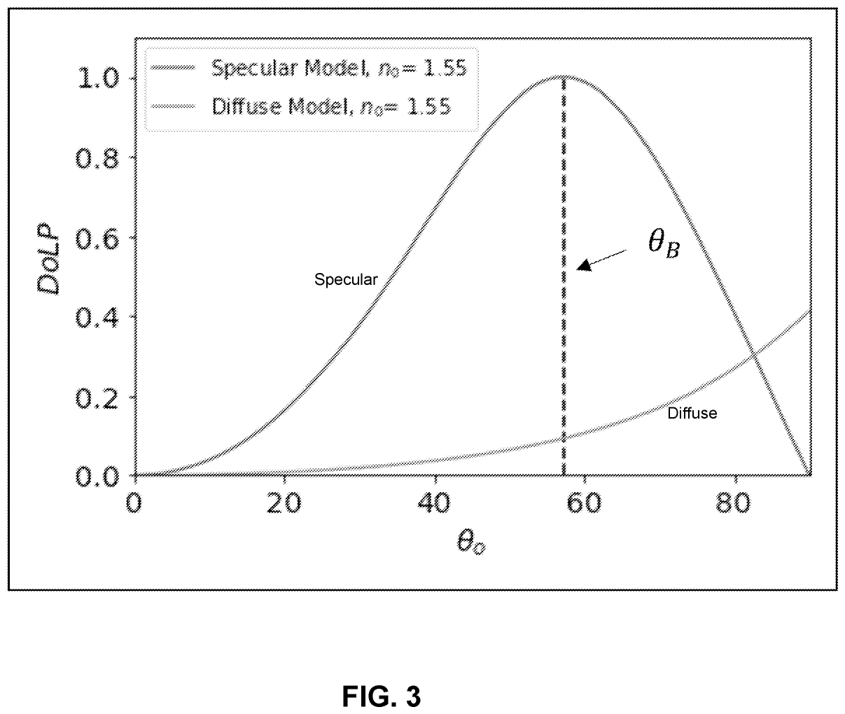

The polarizance DoLP versus AOI for the specular and diffuse model are plotted in FIG. 3. These plots illustrate the viewing angle dependence of polarizance DoLP for specular and diffuse reflection, given in Eq. 4 and Eq. 5; respectively. In the plots, n₀=1.55 and DoLPₛ peaks at Brewster's angle θ_{B}=atan⁻¹ (n₀) while DoLP_{d} increases monotonically with viewing angle.

Here, the DoLPₛ increases up to Brewster's angle. For the diffuse model, DoLP_{d} monotonically increases versus AOI.

The angle of linear polarization (AoLP) is

$$AoLP = \frac{1}{2} {tan}^{- 1} ( \frac{{S}_{2}}{{S}_{1}} ) , \qquad ( 6 )$$

and is bounded between 0° and 180° since AoLP is an orientation, not a vector direction.

The Mueller matrix is a 4×4 real-valued matrix which has, in general, 16 independent parameters and relates an input Stokes vector to an output Stokes vector. If fully-polarized light remains fully polarized, the light-matter interaction is coherent (e.g., non-depolarizing) and the output Stokes vector can be written as

$$\tilde{S} ( \tilde{θ} , \tilde{η} ) = = {{\tilde{S}}_{0} [ \begin{matrix}1 & cos ( \tilde{θ} ) sin ( \tilde{η} ) & sin ( \tilde{θ} ) sin ( \tilde{η} ) & cos ( \tilde{η} )\end{matrix} ]}^{†} . \qquad ( 7 )$$

S is the input Stokes vector and the annotation \hat{·}differentiates a non-depolarizing Mueller matrix from a Mueller matrix with depolarization. The non-depolarizing Mueller matrix has 7 independent parameters: 6 polarimetric parameters plus the average throughput. These matrices are also called pure Mueller matrices or Jones-Mueller matrices because the 7 independent parameters express as a Jones matrix J related to the Mueller matrix by

$$= U ( J ⊗ J \text{*)} {U}^{- 1} \qquad ( 8 )$$

$$where U = [ \begin{matrix}1 & 0 & 0 & 1 \\ 1 & 0 & 0 & - 1 \\ 0 & 1 & 1 & 0 \\ 0 & i & - i & 0\end{matrix} ] .$$

Note that both J and e^{iζ}J are solutions to Eq. 8. In other words, the conversion from a Jones matrix to a Mueller-Jones matrix is insensitive to absolute phase.

Eigenanalysis is the de facto standard method for the analysis of linear systems. However, the eigenvectors of a Mueller matrix are not constrained to be physically-realizable Stokes parameters. Instead, the Mueller matrix can be converted to a Hermitian matrix where eigenanalysis is used to express the Mueller matrix as a convex sum of up to four Mueller-Jones matrices. The Cloude coherency matrix is

$$H = \frac{1}{4} {\sum }_{i , j = 0}^{3} {M}_{ij} {\prod }_{ij} \qquad ( 9 )$$

where Mᵢⱼ is a Mueller matrix element, and the 4×4 matrix Πᵢⱼ is computed from the Pauli spin matrices

$${\prod }_{ij} = \frac{1}{2} U [ {σ}_{i} ⊗ {σ}_{j}^{*} ] {U}^{†} . \qquad ( 10 )$$

$$where$$

$${σ}_{0} = [ \begin{matrix}1 & 0 \\ 0 & 1\end{matrix} ] , {σ}_{1} = [ \begin{matrix}1 & 0 \\ 0 & - 1\end{matrix} ] , {σ}_{2} = [ \begin{matrix}0 & 1 \\ 1 & 0\end{matrix} ] , {σ}_{3} = [ \begin{matrix}0 & - i \\ i & 0\end{matrix} ] . \qquad ( 11 )$$

The inverse relation from Cloude coherency matrix to Mueller matrix is

$$M = {\sum }_{k , l = 0}^{3} {H}_{kl} {\prod }_{kl} . \qquad ( 12 )$$

The coefficients of the Mueller matrix are Mₖₗ=tr(Πₖₗ H). The coefficients of the coherency matrix are

$${H}_{kl} = \frac{1}{4} tr ( {\prod }_{kl} M ) .$$

The eigendecomposition of the Cloude coherency matrix is

$$H = {\sum }_{n = 0}^{R - 1} {ξ}_{n} {c}_{n} {c}_{n}^{†} \qquad ( 13 )$$

where ξₙ is an eigenvalue, R is the rank of the coherency matrix, and cₙ is the associated complex-valued 4×1 eigenvector. If the Mueller matrix in Eq. 9 is physical then H is Hermitian and the eigenvalues are non-negative and sum to one Σₙ^{R}ξₙ=1 (if the Mueller matrix is normalized). The eigenvectors are orthonormal cₖ^{†}cₗ=δₖₗ. Here δₖₗ equals one when k=l and zero otherwise.

Each coherency eigenvector cₙ is related to a Jones matrix

$$\begin{matrix}{J}_{n} & = [ \begin{matrix}{c}_{0 n} + {c}_{1 n} & {c}_{2 n} - {ic}_{3 n} \\ {c}_{2 n} + {ic}_{3 n} & {c}_{0 n} - {c}_{1 n}\end{matrix} ] \\ & = {c}_{0 n} {σ}_{0} + {c}_{1 n} {σ}_{1} + {c}_{2 n} {σ}_{2} + {c}_{3 n} {σ}_{3}\end{matrix} \qquad ( 14 )$$

where the cₙ are also called the complex-valued Pauli coefficients of the Jones matrix. A consequence of the coherency eigenvectors orthonormality is that the associated Jones matrices satisfy

tr[Jₙ^{†}Jₘ]=2δₙₘ. (15)

A Mueller-Jones matrix is denoted \hat{M} because its Cloude coherency matrix is rank one. In other words, the Mueller-Jones matrix can be expressed as a single Jones matrix.

### Triple Degeneracy in the Coherency Eigenspectrum

There are infinite decompositions to express a given Mueller matrix as a weighted sum of other Mueller matrices. The eigendecomposition of the Cloude coherency matrix is a convex sum of up to four Mueller-Jones matrices that can express a given Mueller matrix

$$m = \frac{M}{{[ M ]}_{00}} = {\sum }_{n = 0}^{R - 1} {ξ}_{n} {\hat{m}}_{n} . \qquad ( 16 )$$

Here the coherency eigenvalues are the weights of the Mueller-Jones matrices and the sum is convex because these weights sum to one, Σₙ^{R}ξₙ=1. The lower-case in \hat{m} denotes unit throughput ([\hat{m}]₀₀=1), which is a simple normalization of the Mueller matrix by [M]₀₀. Each normalized Mueller-Jones matrix \hat{m}ₙ is computed from the coherency eigenvectors. The convention of descending-order results in ξ₀≥ξ₁≥ξ₂≥ξ₃. Therefore, the Mueller-Jones matrix \hat{m}₀ will be referred to as the dominant coherent process since the associated eigenvalue is largest.

In the case where the coherency eigenspectrum is triply degenerate (TD) ξ₁=ξ₂=ξ₃ the Mueller matrix simplifies to

$$M = \frac{4 {M}_{00}}{3} [ ( {ξ}_{0} - \frac{1}{4} ) {\hat{m}}_{0} + ( 1 - {ξ}_{0} ) I D ] , \qquad ( 17 )$$

where ID is the Mueller matrix for an ideal depolarizer which is zero in all elements except for the average throughput [ID]₀₀=1. This TD class of Mueller matrices has 8 degrees of freedom: 6 for the dominant coherency eigenvector c₀ which can also be expressed as the Mueller-Jones matrix \hat{m}₀, 1 for the largest coherency eigenvalue ξ₀, and 1 for the average throughput M₀₀.

The TD Mueller matrix in Eq. 17 can be converted to a coherency matrix using Eq. 9 to yield

$$H = \frac{4 {M}_{00}}{3} [ ( {ξ}_{0} - \frac{1}{4} ) {c}_{0} {c}_{0}^{†} + \frac{( 1 - {ξ}_{0} )}{4} I ] \qquad ( 18 )$$

where the coherency matrix of 4ID is the identity matrix I. The coherency matrix of the Mueller-Jones matrix \hat{m}₀ is the rank one matrix c₀c₀^{†}. Note that both c₀ and e^{iξ}c₀ yield the same coherency matrix. The 4×1 vector c₀ is unit length with arbitrary absolute phase leading to 6 degrees of freedom. In general, a coherency matrix is a 4×4 complex-valued Hermitian matrix with 16 degrees of freedom just like the Mueller matrices. However, the TD coherency matrix in Eq. 18 has 8 degrees of freedom just like its associated TD Mueller matrix in Eq. 17.

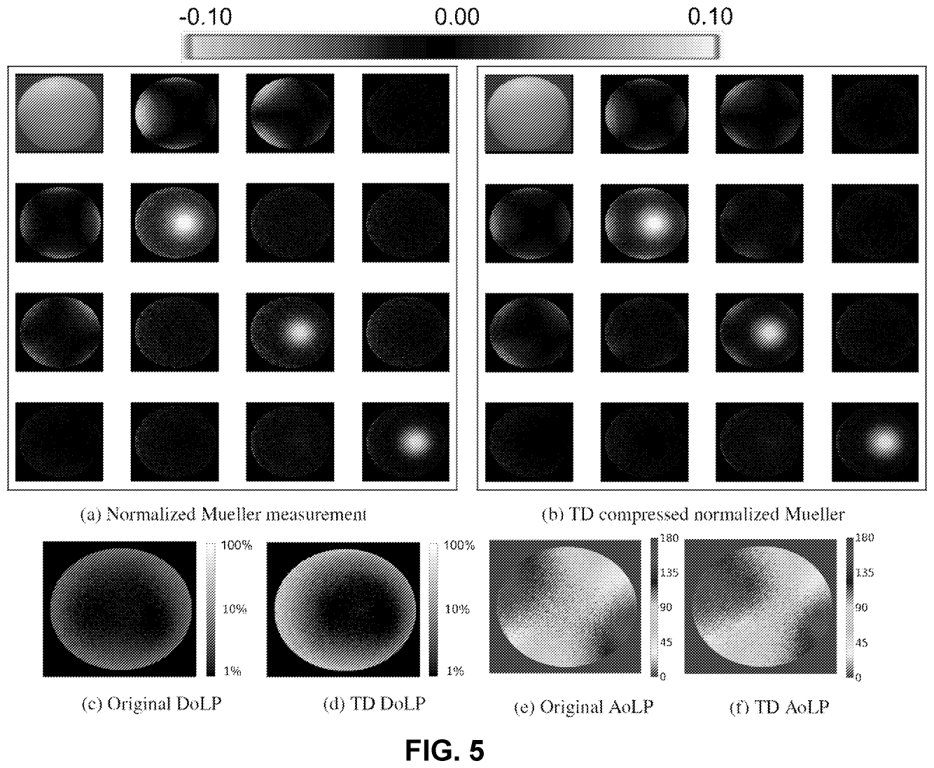

FIG. 5 illustrates Mueller matrix measurements and computed metrics. A normalized Mueller matrix measurement of a pink silicone sphere is shown in panel (a). To aid interpretation the M₀₀ element is replaced by an RGB image of the object at an arbitrary scattering geometry. The RGB950 imaging Mueller polarimeter was used to perform these measurements at 524 nm. Scattering is in-plane and θ_{d}=25° for the center pixel. Panel (b) illustrates the normalized measurement that is compressed to the TD model, see Eq. 17. The DoLP images of the polarizance vector (i.e., first column of the Mueller matrix) are compared in panels (c) and (d), where panel (c) corresponds to the original measurement and panel (d) corresponds to TD compressed. The AoLP images of the polarizance vector are compared in panels (e) for to the original measurement and in panel (f) for compressed. For both AoLP images, the orientation of polarization is approximately normal to the surface of the sphere which is consistent with a diffuse polarized scattering model. The average DoLP and AoLP deviation between these images (see Eq. 41 and Eq. 42) is 0.9% and 21°. The polarizance AoLP of the TD compressed Mueller matrix in panel (f) has smoother spatial variation closer to the on-specular scattering geometry (center of the sphere), as compared to the original measurement in panel (e). This indicates AoLP sensitivity to changes in scattering geometry at smaller angles in the TD compression, which truncates the Mueller matrix to its dominant process, as compared to the original. Often, AoLP is used in computer graphics and computer vision for shape reconstruction. The polarizance AoLP shown in panel (e) can be measured by a linear Stokes camera with unpolarized illumination. The polarizance AoLP in panel (f) is computed from the dominant process and thus a full Mueller measurement is required. Therefore, the enhanced sensitivity to surface geometry in panel (f) compared to panel (e) reflects the retention of more information from the Mueller measurement.

### Polarimetric Importance (Statistical) Sampling

Consider normalizing the Mueller matrix in Eq. 16

$$m = \frac{M}{{M}_{00}} = {\sum }_{n = 0}^{R - 1} {ξ}_{n} {\hat{m}}_{n} \qquad ( 19 )$$

The sum of the normalized coherency eigenvalues is one: Σₙξₙ=1. Therefore, Eq. 19 can be restated as the equivalence between a normalized Mueller matrix and the average value of an ensemble of normalized Mueller-Jones matrices

$$m = \overline{\hat{m}} = 〈 \hat{m} 〉 \qquad ( 20 )$$

where the probability of a Mueller-Jones is Pr(\hat{m}=\hat{m}ₙ)=ξₙ. Any discrete linear process L can be factored out of the expectation or performed prior to the expectation, as in

Lm= [symbol] L\hat{m} [symbol] . (21)

If L is the ray tracing process then implementing the RHS of Eq. 21 makes it possible to model depolarization effects using Jones calculus for light-matter interactions since \hat{m} is a Mueller-Jones matrix.

Depolarization is often described as the result of physically averaging over disorder in a system, e.g., many scattered ray paths inside an integrating sphere. This work is original by treating the Mueller-Jones matrix (or Jones matrix) itself as a random variable in an otherwise deterministic description of the pBRDF.

Depolarization is computed as an expectation, or average-value, of the random Mueller-Jones matrix in the ray trace. Performing an average over the ray trace result, given a Mueller-Jones matrix for each light-matter interaction, allows for coherent states to be propagated through the ray trace and averaged at the detector plane. Similar to sampling ray geometry based on the BRDF, this proposed method importance samples the polarization-dependent parameters of a material's pBRDF.

The normalization by M₀₀ in Eq. 19 is equivalent to factoring out the radiometric BRDF from the pBRDF. This factorization ensures that the eigenvalues sum to one and is necessary for a probabilistic interpretation. An advantage of this normalization is that the normalized polarization model can be scaled by an established BRDF model.

Consider a light-matter interaction for a probabilistic depolarization model with the triple degeneracy assumption. Here, a non-depolarizing Mueller-Jones matrix and the ideal depolarizer Mueller matrix are weighted by two associated probabilities. When this ray hits a material a Mueller-Jones matrix \hat{m} is selected according to the probabilistic distribution

$$M / {M}_{00} = 〈 {m}_{n} 〉 = \{ \begin{matrix}{\hat{m}}_{0} with probability p \\ I D with probability 1 - p\end{matrix} , \qquad ( 22 )$$

where

$$p = \frac{4}{3} ( {ξ}_{0} - \frac{1}{4} )$$

and the Mueller matrix for the ideal depolarizer is ID. Since a Mueller-Jones matrix has an equivalent Jones matrix, the light-matter interaction can be computed in either a Mueller calculus with non-depolarizing Mueller-Jones matrices or in a Jones calculus where the light remains fully coherent. For this triply degenerate case, the two possible Mueller-Jones matrices are the dominate process m₀ and ID. The sampling requires a random number generator to select between \hat{m}₀ or ID a fraction of the time equal to p or 1−p, on average. The polarization ellipse of the ray is modified according to the matrix-vector product in Eq. 7 using the selected matrix to compute the polarization ellipse of the exitant ray. This process is repeated for each light-matter interaction. The Stokes parameters of each ray are averaged at the detector which creates partial polarization states.

Mueller calculus is required to represent partially-polarized states. An advantage offered by polarimetric importance sampling is that light-matter interactions are either completely polarized or unpolarized. Rays can be combined at the detector plane after the ray trace terminates. This would make it possible to compute depolarization from a radiometric ray trace combined with a polarimetric ray trace using Jones calculus. Jones versus Mueller calculus is computational advantageous due to few parameters in the matrices (7 versus 16). Also, quaternions are applicable to Jones (or non-depolarizing Mueller) matrices but not to partially-polarized Mueller matrices. Quaternion rotations are a common tool used to speed up computer graphics.

### Parameters for Probabilistic Coherent Interactions

This section discusses parameterization which would be useful for the implementation of probabilistic coherent light-matter interactions. As opposed to the Mueller matrix elements, the degrees of freedom are expressed in terms of the ensemble of Jones matrices and the associated probabilities.

The 16 degrees of freedom of a Mueller matrix can be correlated with the constraints on the Hermitian coherency matrix. In general, a 4×1 complex-valued vector is defined by 8 real numbers and without constraints the vector has 8 degrees of freedom. Each complex-valued eigenvector e₀ has an arbitrary phase factor which cancels in eₙeₙ^{†} and the constraint for unit magnitude results in 6 degrees of freedom for one of the eigenvectors associated with a non-zero eigenvalue. Since the eigenvectors are orthonormal the next eigenvector must be orthogonal to the first. Therefore only two complex-valued components of the second eigenvector are unconstrained: one component is determine by the unit magnitude constraint and the other for the perpendicular constraint. The third eigenvector is reduced to two degrees of freedom (i.e., a single complex-valued component); one component is determined by the unit magnitude constraint and the other two for the constraint to be perpendicular to two other eigenvectors. Finally, the fourth eigenvector is now completely defined; its direction by the orthonormal constraint and the magnitude is unity. The grand total is 12 degrees of freedom for the eigenvectors of the coherency matrix and 4 for the eigenvalues. The four degrees of freedom for the eigenvalues can be alternatively parameterized by the throughput (which is the sum of the four eigenvalues) and three eigenvalues.

Consider the Mueller-Jones matrix \hat{m}₀ which is the dominant coherent process. The associated coherency eigenvector e₀ represents 6 degrees of freedom. A useful parameterization is:

$${e}_{0} = [ \begin{matrix}cos ( α ) \\ cos ( β ) sin ( α ) {e}^{i {δ}_{1}} \\ cos ( γ ) sin ( β ) sin ( α ) {e}^{i {δ}_{2}} \\ s in ( γ ) sin ( β ) sin ( α ) {e}^{i {δ}_{3}}\end{matrix} ] \qquad ( 23 )$$

where the 6 degrees of freedom are: α, β, γ, δ₁, δ₂, and δ₃. From these parameters a family of orthonormal sets exist. The choice of an orthonormal set which maximizes sparsity is

$${e}_{1} = [ \begin{matrix}- s in ( α ) \\ cos ( β ) cos ( α ) {e}^{i {δ}_{1}} \\ cos ( γ ) sin ( β ) cos ( α ) {e}^{i {δ}_{2}} \\ sin ( γ ) sin ( β ) cos ( α ) {e}^{i {δ}_{3}}\end{matrix} ] \qquad ( 24 )$$

$${e}_{2} = [ \begin{matrix}0 \\ - s in ( β ) {e}^{i {δ}_{1}} \\ cos ( γ ) cos ( β ) {e}^{i {δ}_{2}} \\ sin ( γ ) cos ( β ) {e}^{i {δ}_{3}}\end{matrix} ] \qquad ( 25 )$$

$${e}_{3} = [ \begin{matrix}0 \\ 0 \\ - s in ( γ ) {e}^{i {δ}_{2}} \\ cos ( γ ) {e}^{i {δ}_{3}}\end{matrix} ] . \qquad ( 26 )$$

Here each of these eigenvectors can be expressed as a Jones matrix using Eq. 14 or a Mueller-Jones matrix using Eq. 8. This orthonormal basis about e₀ can form the columns of a unitary matrix

U_{4R}^{†}=(e₀ e₁ e₂ e₃) (27)

where these four orthonormal reference vectors are denoted (4R). It is notable that a unitary matrix multiplied by a diagonal matrix of unit magnitude phasors does not change the associated Mueller-Jones matrices. To rotate U_{4R} to a new unitary matrix U₄ that preserves e₀ consider

$${U}_{4} = {U}_{4 R}^{†} ( \begin{matrix}1 & {0}^{T} \\ 0 & {U}_{3}\end{matrix} ) . \qquad ( 28 )$$

Here U₃ is a 3×3 submatrix with six degrees of freedom to describe the rotation

$${U}_{3} ( {ϕ}_{i} , {ζ}_{i} ) = {U}_{23} ( {ϕ}_{3} , {ζ}_{3} ) {U}_{12} ( {ϕ}_{2} , {ζ}_{2} ) {U}_{13} ( {ϕ}_{1} , {ζ}_{1} ) \qquad ( 29 )$$

$$where$$

$${U}_{13} = ( \begin{matrix}cos ( {ϕ}_{1} ) & 0 & - sin ( {ϕ}_{1} ) {e}^{- i {ζ}_{1}} \\ 0 & 1 & 0 \\ sin ( {ϕ}_{1} ) {e}^{i {ζ}_{1}} & 0 & cos ( {ϕ}_{1} )\end{matrix} ) \qquad ( 30 )$$

$${U}_{12} = ( \begin{matrix}cos ( {ϕ}_{2} ) & - sin ( {ϕ}_{2} ) {e}^{- i {ζ}_{2}} & 0 \\ sin ( {ϕ}_{2} ) {e}^{i {ζ}_{2}} & cos ( {ϕ}_{2} ) & 0 \\ 0 & 0 & 1\end{matrix} ) \qquad ( 31 )$$

$${U}_{23} = ( \begin{matrix}1 & 0 & 0 \\ 0 & cos ( {ϕ}_{3} ) & - sin ( {ϕ}_{3} ) {e}^{- i {ζ}_{3}} \\ 0 & sin ( {ϕ}_{3} ) {e}^{i {ζ}_{3}} & cos ( {ϕ}_{3} )\end{matrix} ) . \qquad ( 32 )$$

The three depolarization angles ϕᵢ are bounded on the interval [0, π/2] and the other three depolarization angles ζᵢ are bounded on the interval [−π, π].

To summarize, the 16 Mueller matrix elements are equivalently parameterized as: six parameters to specify e₀, six parameters to specify the depolarization angles, and four unnormalized coherency eigenvalues to specify the throughput and probabilities of e₀, e₁, e₂, and e₃.

### An Example

Consider a light-matter interaction where a ray has attributes such as direction (given by two direction cosines), a scalar-valued radiance, and a polarization ellipse (given by a latitude and longitude on the Poincare sphere). These parameters are stated in Eq. 7. For a probabilistic depolarization model, the properties of the light-matter interaction are four non-depolarizing matrices and four associated probabilities. When this ray hits a material, a Jones matrix J (or Mueller-Jones matrix \hat{m}) is selected according to the probabilistic distribution

$$M = {M}_{00} 〈 {m}_{n} 〉 = \{ \begin{matrix}{\hat{m}}_{0} or {J}_{0} with probability {ξ}_{0} \\ {\hat{m}}_{1} or {J}_{1} with probability {ξ}_{1} \\ {\hat{m}}_{2} or {J}_{2} with probability {ξ}_{2} \\ {\hat{m}}_{3} or {J}_{3} with probability {ξ}_{3}\end{matrix} . \qquad ( 23 )$$

Since a Mueller-Jones matrix has an equivalent Jones matrix the light-matter interaction can be computed in either a Mueller calculus with non-depolarizing Mueller-Jones matrices or in a Jones calculus where the light remains fully coherent. The numerical implementation of this statistical expectation will require a random number generator to select Jₙ (or \hat{m}ₙ) a fraction of the time equal to ξₙ, on average. The polarization ellipse of the ray is modified according to the matrix-vector product in Eq. 7 using the selected matrix to compute the polarization ellipse of the exitant ray. This process is repeated for each light-matter interaction and depicted in the flow chart of FIG. 1.

Consider the Mueller matrix

$$M = [ \begin{matrix}1. & 0.0085 & - 0.0 \; 001 & 0 \\ 0.0085 & 0.1504 & - 0.0009 & 0 \\ - 0.0000 & 0.0009 & 0.1502 & 0 \\ 0 & 0 & 0 & 0.1502\end{matrix} ] \qquad ( 24 )$$

The component Mueller-Jones matrices and probabilities are

$$\begin{matrix}M = 0.3628 [ \begin{matrix}1. & 0.0564 & - 0.0006 & 0.0000 \\ 0.0564 & 1. & - 0.0062 & 0.0000 \\ - 0.0003 & 0.0 \; 061 & 0.9984 & 0.0000 \\ - 0.0000 & - 0.0000 & 0.0000 & 0.9984\end{matrix} ] + \\ 0.2124 [ \begin{matrix}1. & 0.0082 & 0.0002 & 0.0000 \\ - 0.0082 & - 1. & 0.0 \; 061 & - 0.0000 \\ - 0.0002 & - 0.0 \; 061 & - 0.9999 & 0.0077 \\ 0.0000 & 0.0000 & 0.0077 & 0.9999\end{matrix} ] + \\ 0.2124 [ \begin{matrix}1. & - 0.0564 & - 0.0002 & 0.006 \\ - 0.0564 & 1. & 0.0065 & - 0.0002 \\ - 0.0002 & 0.0065 & - 0.9984 & 0. \\ - 0.006 & 0.0002 & - 0. & - 0.9984\end{matrix} ] + \\ 0.2124 [ \begin{matrix}1. & - 0.0082 & 0.0006 & - 0.0060 \\ 0.0082 & - 1. & - 0.0065 & 0.0002 \\ 0.0007 & - 0.0065 & 0.9999 & - 0.0077 \\ 0.0060 & - 0.0002 & - 0.0077 & - 0.9999\end{matrix} ]\end{matrix} \qquad ( 25 )$$

where the probabilities are ξ=[0.3628, 0.2124, 0.2124, 0.2124] and each matrix in Eq. 30 is a Mueller-Jones matrix.

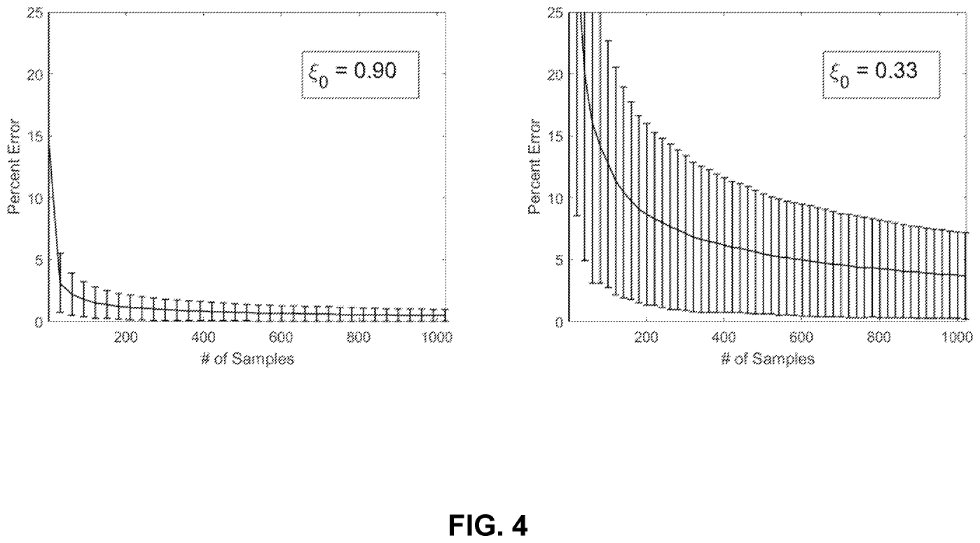

The selection of the Jones or Mueller-Jones matrices in Eq. 30 is expected to converge to the true mean, in Eq. 29 with repeated independent trials. The higher the entropy of the probabilities (i.e., the closer to a uniform distribution) the greater than quantity of samples required for convergent solutions. To demonstrate asymptotic performance two cases are selected: ξ₀=0.90 and ξ₀=0.33 as examples of the best and worse case, respectively. The probabilities are assumed to be triple-degenerate so that ξ₁=ξ₂=ξ₃=⅓(1−ξ₀). In FIG. 4, the mean and standard deviation of the percent error between the true depolarizing Mueller matrix and the sample mean is reported for up to 1,000 samples. For both of these cases the average error is below 6% above 500 samples; see FIG. 4. In the best-case scenario, the average error is below 6% above only 10 samples. In computer graphics applications, a minimum of 512-1024 rays are traced for each pixel and photo-realistic renderings can require even more samples. The requirement for number of rays traced is not expected to increase when implementing probabilistic coherent light-matter interactions as compared to a current deterministic methods.

### Further Notes for Triple Degenerate Probabilities

The coherency matrix H can be expressed as 16 degrees of freedom in an alternative parameterization: 6 depolarization angles, 4 eigenvalues, and 6 degrees of freedom for the dominant coherent process e₀

$$H = {U}_{4} ( {ϕ}_{i} , {ζ}_{i} ) ( \begin{matrix}{Ξ}_{0} & 0 & 0 & 0 \\ 0 & {Ξ}_{1} & 0 & 0 \\ 0 & 0 & {Ξ}_{2} & 0 \\ 0 & 0 & 0 & {Ξ}_{3}\end{matrix} ) {U}_{4}^{†} ( {ϕ}_{i} , {ζ}_{i} ) . \qquad ( 26 )$$

The importance of this parameterization is that often the dominant coherent process is known a priori and the number of necessary depolarization angles to specify a Mueller matrix is reduced if there is degeneracy in the coherency eigenspectrum.

In the case where coherency eigenspectrum has the property Ξ₁≈Ξ₂≈Ξ₃ (referred to as triple degeneracy), the six depolarization angles defined in Eq. 29 do not change the coherency matrix in Eq. 31. The coherency matrix simplifies to

$$H = {U}_{4 R} ( \begin{matrix}{Ξ}_{0} & 0 & 0 & 0 \\ 0 & {Ξ}_{1} & 0 & 0 \\ 0 & 0 & {Ξ}_{1} & 0 \\ 0 & 0 & 0 & {Ξ}_{1}\end{matrix} ) {U}_{4 R}^{†} . \qquad ( 27 )$$

This class of Mueller matrices has 8 degrees of freedom: 6 for e₀ and 2 for the unique coherency eigenvalues. If the dominant coherent process is known a priori than the material is parameterized by two degrees of freedom: the throughput, i.e., M₀₀=ΣₙΞₙ, and the fractional contribution of the dominant process ξ₀=Ξ₀/M₀₀.

### Fresnel Dominant and Triple Degenerate Probabilities

The Jones matrix for Fresnel reflection is

$${J}_{0} = R ( {α}_{o} ) ( \begin{matrix}s & 0 \\ 0 & p\end{matrix} ) R ( - {α}_{i} ) , \qquad ( 28 )$$

where s and p are complex-valued Fresnel reflection coefficients, αᵢ is the angle from the plane of incidence to the scattering plane and αₒ is the angle from scattering plane to the plane containing the exiting ray and the surface normal. The six parameters of the Fresnel reflection matrix can be expressed as the six depolarization angles; consider defining Σ=s+p and Δ=s−p. Then,

$$α = arccos ( \frac{\vert \sum cos ( {α}_{i} - {α}_{o} ) \vert}{\sqrt{\vert Δ {\vert}^{2} + \vert \sum {\vert}^{2}}} ) , \qquad ( 29 )$$

$$β = arccos ( \frac{\vert Δcos ( {α}_{i} + {α}_{o} ) \vert}{\sqrt{\vert Δ {\vert}^{2} + \vert \sum {\vert}^{2} {sin}^{2} ( {α}_{i} - {α}_{o} )}} ) , \qquad ( 30 )$$

$$γ = arccos ( \frac{\vert Δsin ( {α}_{i} + {α}_{o} ) \vert}{\sqrt{\vert \sum {\vert}^{2} {sin}^{2} ( {α}_{i} - {α}_{o} ) + \vert Δ {\vert}^{2} {sin}^{2} ( {α}_{i} + {α}_{o} )}} ) \qquad ( 31 )$$

$${δ}_{1} = {δ}_{2} = arg ( Δ ) - arg ( \sum ) \qquad ( 32 )$$

$${δ}_{3} = arg ( - i \sum ) - arg ( \sum ) . \qquad ( 33 )$$

In the special case of in-plane scattering, αᵢ=αₒ=0 which results in β=γ=0.

To compute the sparse eigenvector solution set when Fresnel reflection is the dominant process the depolarization angles expressed as Fresnel parameters can be substituted in Eqs. 23, 24, 25 and 26 for e₀, e₁, e₂, and e₃; respectively. However due to the triple degenerate eigenspectrum (see Eq. 32), the e₁, e₂ and e₃ eigenvectors are equally-weighted. Therefore, the depolarization angles can rotate e₁, e₂ and e₃ about e₀ arbitrarily. In this case, the depolarization angles which result in the sparse set solution is a specific choice made to reduce the number of non-zero elements which need to be computed.

Example KAIST pBRDF Dataset and Model Geometry

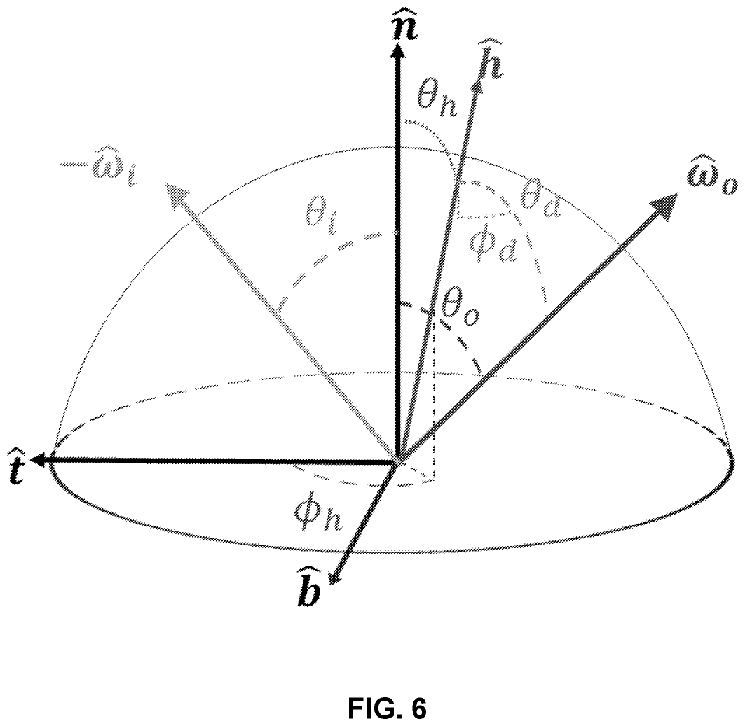

The KAIST dataset stores the wavelength-dependent pBRDFs for 25 materials as a 6-dimensional tensor where the scattering geometry is specified in a Rusinkiewicz coordinate system. The pBRDF is defined in the local tbn-space in the direction of light travel as shown in FIG. 6, where \hat{ω}ᵢ and \hat{ω}ₒ are the incident and outgoing directions, respectively. The Rusinkiewicz coordinates in FIG. 6 specifies acquisition geometry using the zenith and azimuth difference angles (θ_{d} and ϕ_{d}) as well as, zenith halfway angle (θₕ). The microfacet model postulates that for every \hat{ω}ᵢ to \hat{ω}ₒ there is a sub-resolution facet that creates a specular reflection. The surface normal of a microfacet is called the halfway vector h and is calculated by

$$h = \frac{{\hat{ω}}_{o} - {\hat{ω}}_{i}}{\vert {\hat{ω}}_{o} - {\hat{ω}}_{i} \vert} . \qquad ( 39 )$$

For in-plane scattering, the zenith angle of the halfway vector θₕ=0. Since the materials are isotropic, they are invariant to the azimuth angle of the halfway vector ϕₕ. Changing this halfway azimuth angle would be equivalent to rotating a sample about its surface normal. The angle of incidence on the facet is called the difference angle θ_{d} and is related to the incident direction and facet surface normal by

$${θ}_{d} = arccos ( h \cdot ( - {\hat{ω}}_{i} ) ) . \qquad ( 40 )$$

The azimuth difference angle ϕ_{d} is the azimuth angle of −\hat{ω}ᵢ after a rotation to make h and n parallel. Isotropic BRDF databases often assume a bilateral symmetry that truncates the range of ϕ_{d} to [0,π]. Polarimetry breaks bilateral symmetry. Scattering above, or below, the plane of incidence are distinct geometrical transforms for linear polarization. Therefore, the pBRDF database parameterizes ϕ_{d} in the range [−π,π].

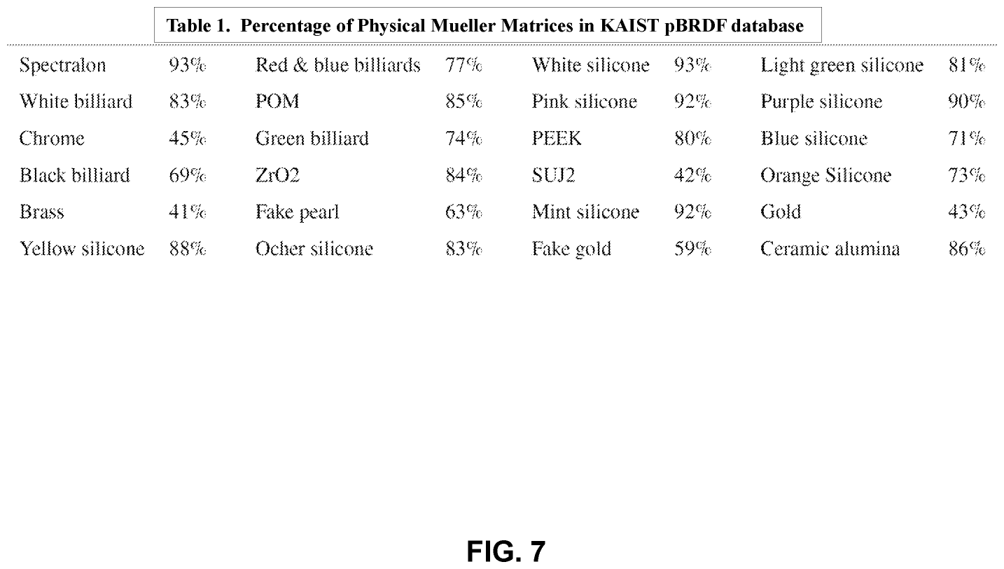

Not all entries in the KAIST pBRDF database correspond to physical Mueller matrices. A necessary and sufficient condition for the Mueller matrix to be non-physical is if any of the eigenvalues of the coherency matrix are negative. The condition for physical Mueller matrices used in this work differs from other techniques, which instead use the percentage of valid Stokes matrices. Table 1 in FIG. 7 reports the percentage of physical Mueller matrices for each material in the KAIST pBRDF database. The diattenuation is the polarization-dependence of the reflectance. Objects with lower diattenuation, such as silicone and spectralon, have a larger percentage of physical Mueller matrices. Diffuse objects are easier to measure with a polarimeter compared to specular objects such as gold or brass which have a larger diattenuation. There are fewer physical Mueller measurements for materials of higher diattenuation (e.g., metals) since a larger dynamic range in the detection process is required. Non-depolarizing materials are also more likely to create nonphysical Mueller reconstructions because even slight perturbations by measurement noise can create measurements that are inconsistent with physical Mueller matrices.

Each material in the KAIST Mueller database is measured at 2,989,441 scattering geometries and four wavelengths. As noted above, if the eigenvalues of the coherency matrix corresponding to each Mueller matrix are non-negative then the Mueller matrix is physical; see Eq. 13. There are fewer physical Mueller measurements for materials of higher diattenuation (e.g., metals) since a larger dynamic range in the detection process is required. Non-depolarizing materials are also more likely to create nonphysical Mueller reconstructions because even slight perturbations by measurement noise can create measurements that are inconsistent with physical Mueller matrices.

For each material, the entries of the KAIST Mueller database are stored as a single-precision elements resulting in a 912 Mb tensor of shape (361×91×91×5×4×4). Here the dimensions correspond to (ϕ_{d}, θ_{d}, θₕ, λ, and M). The eight TD parameters replace the 16 Mueller matrix elements compressing the database to 361×91×91×5×4×2, resulting in a 456 Mb file per material. No assumptions are made regarding the dominant coherent process for each acquisition geometry. Here, the 4×2 matrix contains six real-valued numbers to describe the complex-valued 4×1 coherency eigenvector c₀ (see Eq. 13), the largest coherency eigenvalue ξ₀, and the average throughput M₀₀. The coherency eigenvector is unit length and the absolute phase is arbitrary (see Eq. 18), therefore six parameters specify c₀. Therefore, the first element of c₀ can be made real-valued and computed from the magnitudes of the other three elements.

The procedure to form the TD pBRDF database from the original Mueller matrices starts by storing M₀₀ in the TD database and then the Mueller matrix is normalized by this number. The normalized Mueller matrices are converted to Cloude coherency matrices using Eq. 9 and eigenanalysis is performed. This eigenanalysis reveals non-physical Mueller matrices as discussed in Sec. 3.1. The largest eigenvalue ξ₀ is rounded to either 0.25 or 1.0 if the eigenvalue is out of this range. The largest eigenvalue is stored in the TD database. Any negative eigenvalues are set to zero which is a standard physical constraint. The c₀ vector is the eigenvector of the Cloude coherency matrix associated with the largest eigenvalue. This vector is unit length and is scaled by a phasor to make the first element real. The real and imaginary parts of the other three elements are stored in the TD database. To convert the TD database into a Mueller matrix c₀ forms a Mueller-Jones \hat{m}₀ which is substituted into Eq. 17. The TD pBRDF databases, as well as modified Mitsuba 2 plug-ins, are available as supplementary materials.

### On-Specular Renderings

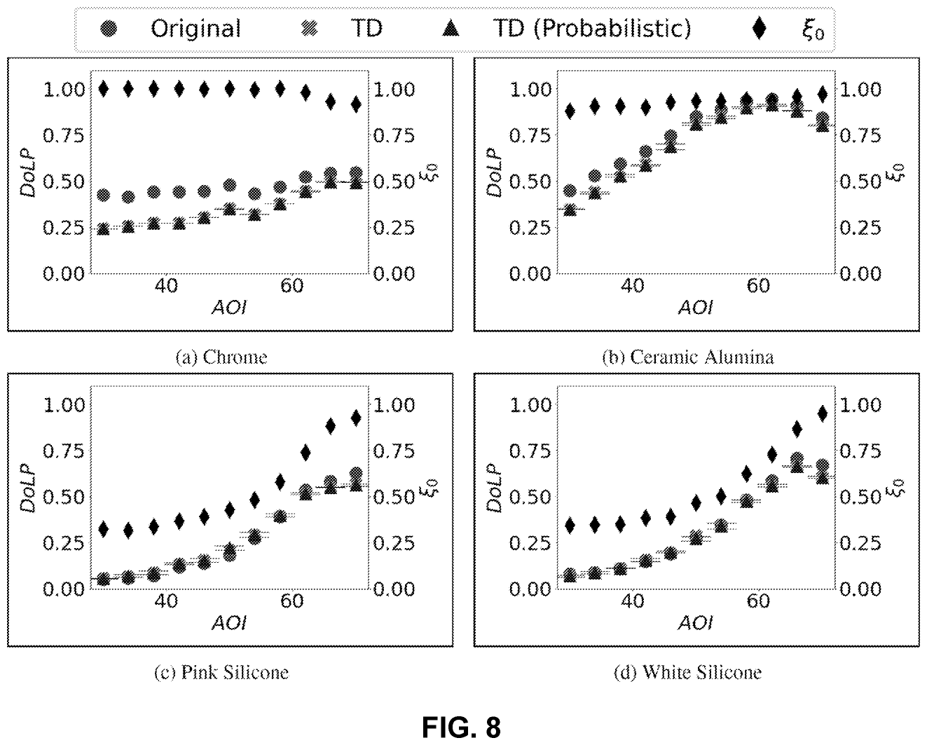

Renderings using unpolarized illumination and specular acquisition geometries were computed for chrome, ceramic alumina, pink silicone, and white silicone. The DoLP of the polarizance vector measures the degree of unpolarized light becoming linearly polarized after reflection. Depolarization describes a reduction in the degree of polarization by a light-matter interaction. The rendered polarizance DoLP versus AOI is shown in FIG. 8 using the pBRDF of the 16 original Mueller matrix elements, pBRDF of 8 TD elements, and the pBRDF of 8 TD elements with polarimetric sampling, see Eq. 17 for the description of the TD elements. The depolarization parameter ξ₀ is also included. Both DoLP and ξ₀ increase with AOI for diffuse materials such as pink FIG. 4c and white FIG. 4d silicone. This monotonic increase is consistent with the Fresnel transmission model, see FIG. 3. Under red illumination, the DoLP for the pink silicone is 2% less than white silicone for all measured angles which is consistent with Umov's effect, which is the inverse relation between the albedo and polarizance.

FIG. 8 illustrates example on-specular polarizance DoLP and the depolarization parameter ξ₀ versus angle of incidence (AOI) renderings from Mitsuba 2 at the wavelength 622 nm for: chrome (panel (a)), ceramic alumina (panel (b)), pink silicone (panel (c)), and white silicone materials (panel (d)). Results for the original 16-element Mueller matrix pBRDF (circles), TD pBRDF (X marks), and the mean and standard deviation for the importance sampled TD pBRDF (triangle) are compared. The black diamonds are the depolarization parameter ξ₀ from Eq. 17. The materials in panels (a) and (b) are close to non-depolarizing and therefore ξ₀ is above 0.9 at all AOIs. While both materials are highly non-depolarizing, the polarizance of the dominant process varies. Material properties such as the refractive index and absorption affect the dominant process. The silicone materials in panels (c) and (d) have a depolarization trend that increases with AOI. The polarizance DoLP of the ceramic material under on-specular illumination trends towards the DoLP of the polarizance vector of the Fresnel reflection Mueller matrix with n₀=1.55. The polarizance DoLP also usually increases with AOI with the exception of the peak at 57° in panel (b) which resembles Brewster's angle as shown in FIG. 3. The maximum deviation between the TD and original DoLP is 0.08 and usually is much lower except for the chrome material shown in panel (a). Only 45% of the chrome measurements are physical (see Table 1) which creates unavoidable deviations since TD is physically constrained. For a relatively small number of rays samples per pixel (spp), spp=64, the polarimetric importance sampled TD converges to the partially-depolarizing Mueller matrix TD pBRDF. In particular, in all cases, the probabilistic implementation of the TD 8-parameter pBRDF converges to the deterministic results using 64 spp.

### Convergence Test of Polarimetric Importance Sampling

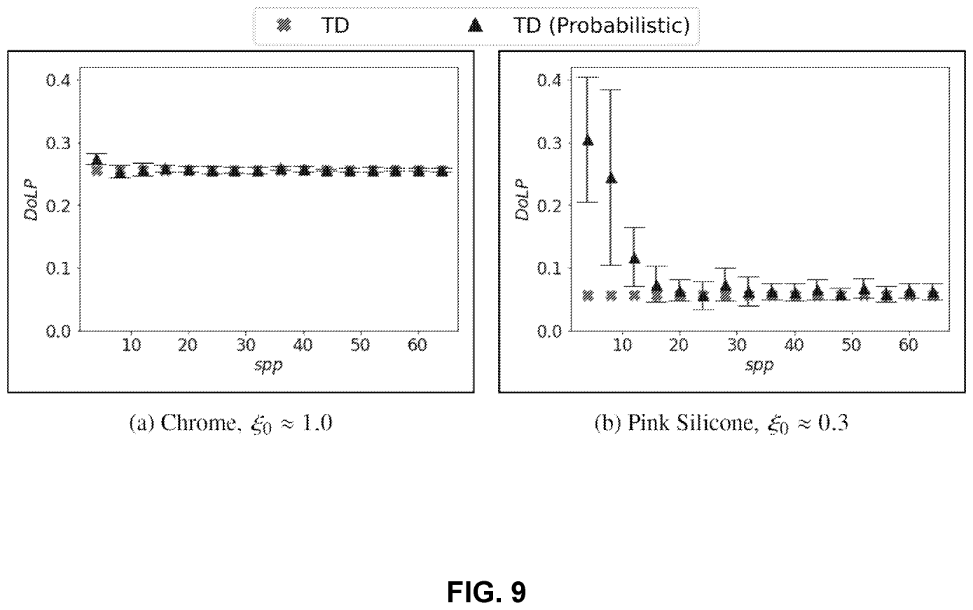

Example convergence properties of the polarimetric importance sampled TD pBRDF (see Eq. 22) with respect to spp is shown in FIG. 9. Here the rendered polarizance DoLP of the polarimetric importance sampled TD pBRDF (triangles) is compared to the TD pBRDF (X marks) in partially-depolarizing Mueller matrix form (see Eq. 17). The error bars are one standard deviation from ten independent trials of the polarimetric importance sampling. The sampled ray geometry is fixed in a specular configuration (AOI=30°), hence the TD pBRDF DoLP does not change with spp. The DoLP from a pBRDF computed with polarimetric importance sampling for chrome, panel (a), reaches an asymptotic value for a lower spp compared to pink silicone, panel (b). In general, a lower ξ₀ indicates more depolarization and a higher entropy of the coherency eigenspectrum. In the extreme cases that ξ₀=1 or ξ₀=0.25 the probabilities for a non-depolarizing or completely depolarizing interaction become certainties (see Eq. 22) and there is no probabilistic variance. The probabilities of a non-depolarizing or completely depolarizing interaction are equal when ξ₀=0.375. Convergence to the same solution as a partially-depolarizing Mueller matrix can be expected to require a higher spp as these probabilities approach equality.

### Methods and Figures of Merit to Compare Rendered Images

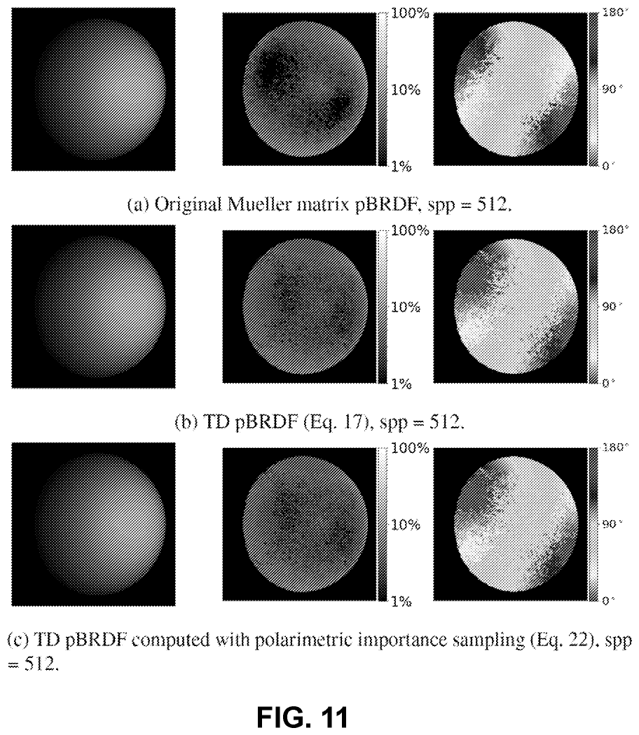

Example renderings are generated using Mitsuba 2, a polarization-aware PBR engine. The number of spp varies for each scene to reach visually assessed convergence. The Stokes images are rendered from an unpolarized source. For s₀, a composite S₀ of the red, green, and blue wavebands is formed and then normalized by the largest pixel value in each color band. The AoLP and DoLP images rendered at the wavelength of 633 nm are shown in FIGS. 11-13. Each scene is rendered using the pBRDF of the original Mueller database, the TD compressed database, and TD with polarimetric importance sampling, as described earlier in this patent document.

When user-defined pBRDF databases are input to Mitsuba 2, continuous random variables are sampled to create independent ray directions. This process requires interpolation of the pBRDF database to unmeasured acquisition geometries. There are various methods to interpolate complex numbers and each offers different advantages. Interpolating the real and imaginary part of two complex numbers forms a line between them in the complex plane. Interpolating the magnitude and phase of two complex numbers forms an arc between them in the complex plane. In this work, linearly interpolating the real and imaginary parts of the six c₀ parameters is required since phase unwrapping is not a current functionality of the Mitsuba 2 pBRDF interpolation. Unfortunately, this constraint yields lower interpolated magnitudes as compared to polar coordinate interpolation. These lower interpolated magnitudes created higher interpolated magnitudes when the first element of c₀ was computed from the magnitudes of the other three elements. This bias in the interpolated magnitudes created a distinct geometric region where the polarizance DoLP was incorrectly zero. Over-parameterizing the TD model by including an additional parameter for c₀ minimizes this artifact. Phase unwrapping for complex-valued parameters in the pBRDF interpolation would be a more elegant solution that is unavailable at this time. Therefore, the TD model used in this work contains nine parameters with eight degrees of freedom. Using nine parameters, the dimensions for each material in the database is 361×91×91×5×3×3 where which file size is 513.2 Mb.

The rendered images from various pBRDF databases are quantitatively compared using two figures of merit: the average DoLP and AoLP standard deviation. The average DoLP variance between two images: DoLP^{a} and DoLP^{b} over all pixels is

$${σ}^{2} ( {DoLP}^{a} , {DoLP}^{b} ) = \frac{1}{N} {\sum }_{n = 1}^{N} {‖ ( {DoLP}_{n}^{a} - {DoLP}_{n}^{b} ) ‖}^{2} , \qquad ( 41 )$$

where N is the total number pixels, and n is the pixel index. The AoLP variance between two images: AoLP^{a} and AoLP^{b} is computed by

$${σ}^{2} ( {AoLP}^{a} , {AoLP}^{b} ) = \frac{1}{N} {\sum }_{n = 1}^{N} {‖ ( {AoLP}_{n}^{a} - {AoLP}_{n}^{b} ) ‖}^{2} = \frac{1}{N} {\sum }_{n = 1}^{N} {[ \frac{1}{2} acos ( \frac{{r}_{n}^{a} \cdot {r}_{n}^{b}}{\vert {r}_{n}^{a} \vert \vert {r}_{n}^{b} \vert} ) ]}^{2} . \qquad ( 42 )$$

where the vector form of the linear Stokes parameters is r=[S₁, S₂]. Using the dot product of this vector to compute the angular difference prevents phase wrapping effects caused by the subtraction of AoLP values that does not account for the proximity of AoLP=0° and AoLP=180°.

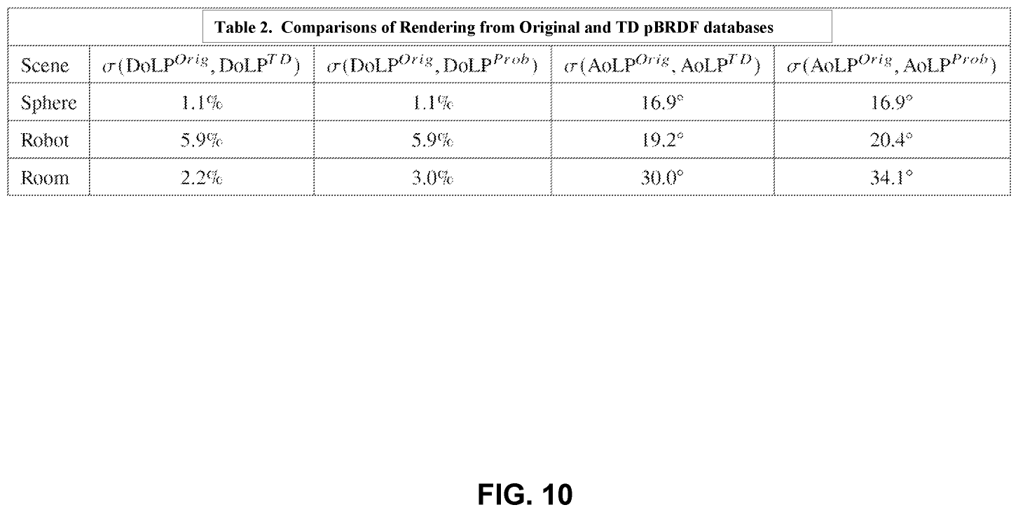

Table 2 in FIG. 10 provides figures of merit to compare renderings from three different pBRDF databases. The average DoLP and AoLP deviation between images a and b is denoted σ(DoLP^{a},DoLP^{b}) and σ(AoLP^{a},AoLP^{b}) in Eq. 41 and Eq. 42, respectively. In the table superscripts denote the original pBRDF, TD pBRDF, and TD pBRDF computed using polarimetric importance sampling. The number of rays required for the probabilistic importance sampling to converge to the partially-depolarizing Mueller matrix implementation is a function of the scene geometry and ray path depth. The sphere uses direct illumination where there is only a single surface reflection. For visual convergence, all rendered spheres use an spp=512. For the robot and room scene, spp=2,048 and spp=4,096 for convergence, respectively for all rendered pBRDFs excluding the probabilistic pBRDF. Here, the probabilistic pBRDF requires additional rays and converges when spp=4,096 and spp=16,384 for the robot and room scene, respectively. These scenes include indirect illumination configurations which require additional rays for the polarimetric importance sampled pBRDF to converge.

### Example Sphere Renderings

Polarimetric renderings of polarizance AoLP and DoLP of a pink silicone sphere are shown in FIG. 11 using the original pBRDF KAIST database (panel (a)), the compressed TD pBRDF database (panel (b)), and the TD pBRDF database computed with importance sampling (panel (c)). The renderings correspond to RGB, DoLP, and AoLP images (left to right columns). The angle between the light source and camera is 25°. Table 2 in FIG. 10 reports summary statistics of the comparisons. The DoLP deviation (see Eq. 41) as compared to the original pBRDF is 1.1% for both the TD pBRDF and the TD pBRDF with polarimetric importance sampling. The AoLP deviation (see Eq. 42) as compared to the original is 16.9° for both the TD pBRDF and the TD pBRDF with polarimetric importance sampling.

In panel (c) the DoLP and AoLP polarizance renderings are computed using polarimetric importance sampling with 512 spp visually converging to the partially-depolarizing Mueller matrix rendering in panel (b). The rendered polarizance AoLP is normal to the surface (which matches the diffuse light scattering model (see Eq. 5) and the measured AoLP shown in FIG. 5) and the DoLP increases radially for this material due to diffuse reflection. Measurements of a pink silicone sphere reported in FIG. 5 have a consistent polarizance AoLP and DoLP dependency. This result suggests that the dominant Mueller-Jones matrix is similar to Fresnel transmission. Both the TD compression of the measurement and the rendering from the KAIST database maintains most of this pattern in the polarizance AoLP and DoLP. An area of disagreement in the AoLP is close to the center of the sphere. The variation in AoLP is larger, compared to the measurement and the rendering from original KAIST database, for the TD pBRDF. At these acquisition geometries the viewing angle is relatively small and the TD pBRDF polarizance AoLP in panel (b) is more sensitive to changes in the surface geometry, as compared to the renderings from the original KAIST database in panel (a). A similar effect was noted and discussed in FIG. 5 when measurements were compressed to the TD model. Another area of disagreement is along the edges of the sphere. Here, the TD assumption does not capture the variations of the DoLP for larger acquisition angles which leads to higher values compared to the original pBRDF.

### Example Scene Renderings

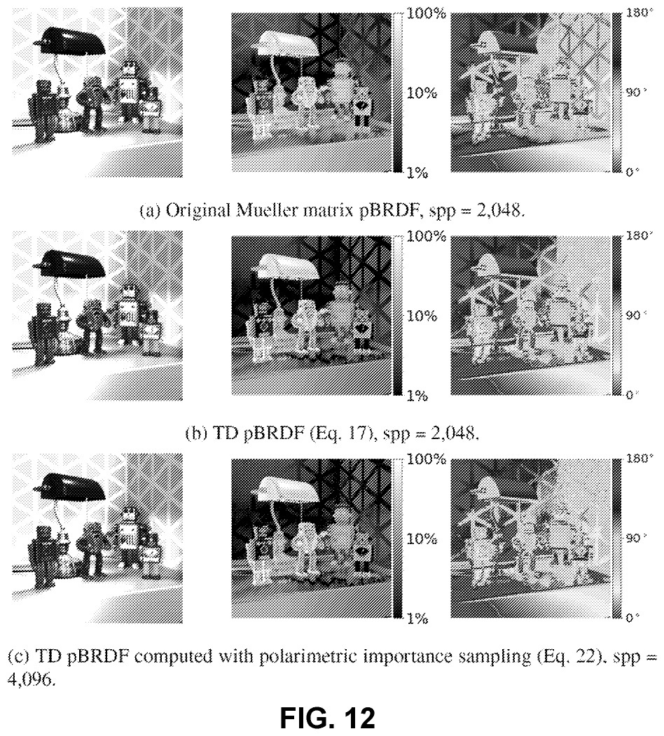

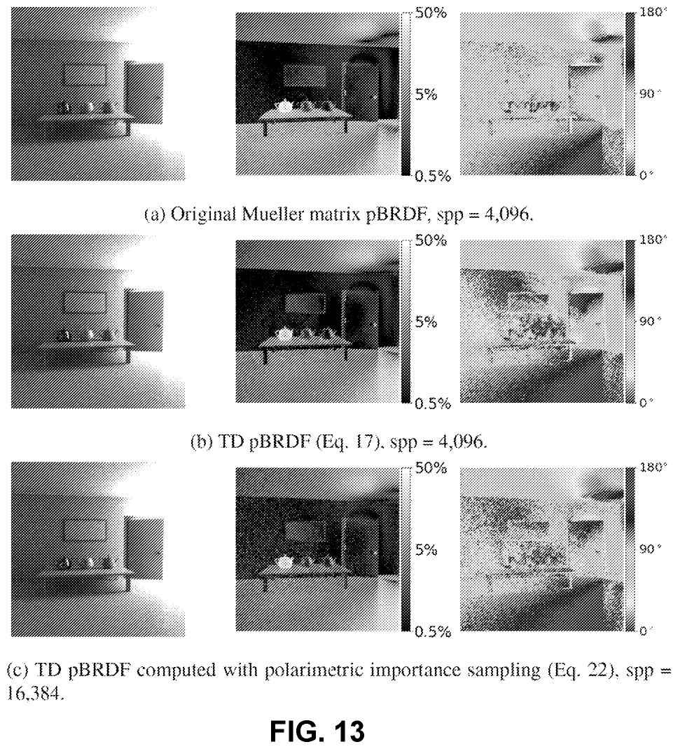

Two scenes containing multiple surface interactions are rendered in FIG. 12 and FIG. 13. All objects use materials from the KAIST pBRDF database. FIG. 12 replicates a robot scene that has also been the subject of analysis in prior techniques. FIG. 13 is a scene where three teapots sit on a table and light enters the room from an ajar door. The teapot material (left to right) is: chrome, ceramic alumina, and pink silicone. Both scenes include indirect scattering events so the path depth is unlimited. In each of FIGS. 12 and 13, RGB, DoLP, and AoLP renderings are shown from left to right columns, where panel (a) corresponds to the original pBRDF KAIST database, panel (b) corresponds to the compressed TD pBRDF database, and panel (c) corresponds to the TD pBRDF database computed with importance sampling. For the probabilistic implementation, FIG. 12 and FIG. 13, require spp=4,096 and spp=16,384, respectively, to reach visually assessed convergence. The variation in spp requirement is due to ray depth. The deviation between the renderings using the TD pBRDF and the original KAIST pBRDF are reported in Table 2 of FIG. 10.

In FIG. 12, the DoLP deviation (see Eq. 41) as compared to the original pBRDF database is 5.9% for the TD pBRDF and the TD pBRDF with polarimetric importance sampling. Umov's effect is evident with the low DoLP for the red pieces of the robot and a high DoLP for the blue pieces. The AoLP deviation (see Eq. 42) as compared to the original pBRDF database is 19.2° for the TD pBRDF and 20.4° for the TD pBRDF with polarimetric importance sampling. The most notable area of AoLP disagreement between original and TD renderings are in the upper right corner on the shaded wall. The green triangle and white stripes on the walls are made of mint silicone and ceramic alumina, respectively. The AoLP renderings of mint silicone are in closer agreement as compared to the ceramic alumina. Differences between the original and TD pBRDFs for ceramic alumina were noted at low AOI in FIG. 8, panel (b). In the shadowed region, more noise is observed in the probabilistic TD rendering than the partially-depolarizing Mueller matrix rendering.

In FIG. 13 the DoLP deviation (see Eq. 41) as compared to the original pBRDF database is 2.2% for the TD pBRDF and 3.0% for the TD pBRDF with polarimetric importance sampling. The AoLP deviation (see Eq. 42) as compared to the original pBRDF database is 30.0° for the TD pBRDF and 34.1° for the TD pBRDF with polarimetric importance sampling. The rendered polarizance AoLP of the TD pBRDF is more sensitive to surface geometry, as compared to the original KAIST pBRDF. This same effect was noted in FIG. 5 and FIG. 11 for measured and rendered spheres; respectively. Differences between the TD AoLP in panel (b) of FIG. 13 and original pBRDF in panel (a) can be observed on the door where the AoLP=90° at the center of the door. For the TD renderings, the AoLP rotates counterclockwise towards 135° and clockwise towards 45° for the top and bottom of the door, respectively. The rendering using the original KAIST pBRDF is insensitive to this geometric change in view direction. Illumination on the left side of the scene is due to indirect scattering events. In this region of the scene, the ray depth is highest and the probabilistic rendering appears more noisy compared to the other renderings.

The experimental results corroborate the advantages of the disclosed techniques that, among other features and benefits, provide compression which retains dominant polarimetric properties, interpolation to non-measured geometries which maintains physical constraints, and convergence tests of polarimetric importance sampling.

It should be noted that the materials in the KAIST database include highly diffuse depolarizing materials (e.g., pink silicone), as well as non-depolarizing metals (e.g., chrome); see Table 1 in FIG. 7. An 8 parameter physically constrained model for 4×4 Mueller matrices for the 25 materials in the KAIST pBRDF database has been tested. Comparisons between the original and compressed TD databases were done by generating polarimetric renderings of scenes containing multiple surface interactions, non-trivial ray depth, and varying surface geometries. For a rendered pink silicone sphere with a single surface interaction, the average DoLP deviation was 1.1% for both the TD compressed and probabilistic TD compressed pBRDF model as compared to the uncompressed model. The deviation in the AoLP between the TD and the original pBRDF is 16.9°. Other rendering comparisons are reported in Table 2 in FIG. 10.

The retention of physically constrained Mueller matrices when interpolating to non-measured geometries is an advantage offered by the TD database. However, the experiments were limited by the need for phase unwrapping to interpolate complex-numbers. A 9-parameter version of the TD database that includes a dependent variable was created to avoid interpolation artifacts. A more complete and satisfactory solution would require an interpolation scheme designed for complex-numbers that were described earlier.

The Mueller matrix expression of the TD model can be restated as the average value of a normalized Mueller-Jones matrix and a completely depolarizing Mueller matrix. A new method of polarimetric importance sampling was demonstrated by relating the depolarization parameter to the probability of a coherent/fully polarized or an unpolarized light-matter interaction. Mueller calculus is required to represent partially-polarized states. An advantage offered by polarimetric importance sampling disclosed herein is that light-matter interactions are either completely polarized or unpolarized. Rays can be combined at the detector plane after the ray trace terminates. This would make it possible to compute depolarization from a radiometric ray trace combined with a polarimetric ray trace using Jones calculus. While the probabilistic importance sampling in this work was computed using a Mueller polarimetric rendering engine, a potential computational advantage would be to use a Jones formalism. Jones calculus requires fewer parameters to describe material polarization properties and to track the polarization state upon light-matter interactions. In addition, quaternion mathematics which already exist for most PBR rendering engines may simplify and decrease computation time for operations in a Jones formalism as compared to Mueller calculus. While to produce the example results, the pBRDF and ray direction were sampled independently, convergence and realism can be improved by coupling pBRDF and ray direction importance sampling.

I/We claim:

1. A method for tracing rays of light in a system that includes one or more depolarizing components, the method comprising:
generating an incoming polarized ray, wherein the incoming ray is characterized by parameters including a direction, a radiance, and a polarization state;
determining an exitant ray of the system using a probabilistic computation after interaction with the one or more depolarizing components, wherein each depolarizing component is characterized by four Jones matrices and four scalar numeric values associated with probabilities of the four Jones matrices, the determining comprising:
selecting a Jones matrix from the four Jones matrices and using the selected Jones matrix and the parameters of the incoming ray to compute a direction and a radiance of the exitant ray after interaction with a material that is at least partially depolarizing; and
repeating the steps of generating an incoming ray and determining an exitant ray one or more times to produce one or more exitant rays until a convergence criterion is reached.

2. The method of claim 1, comprising performing one or more polarimetric measurements to obtain a fractional contribution of fully-polarized versus unpolarized light upon interaction with the one or more depolarizing components, and using the fractional contribution to determine a contribution associated with a partially-polarized light as part of the determining the exitant ray after interaction with the one or more depolarizing components.

3. The method of claim 1, wherein the selecting the Jones matrix is performed based on the four probability values.

4. The method of claim 1, wherein the convergence criterion includes one of:
completion of tracing a predetermined number of rays, or
upon reaching a condition where a characteristic of an exitant ray remains substantially unchanged compared to one or more previous exitant rays.

5. The method of claim 1, comprising obtaining the four scalar numeric values using a linear transform that converts a Mueller matrix associated with the one or more depolarizing components in a Hermitian form.

6. The method of claim 4, wherein the four scalar numeric values are eigenvalues of a Hermitian matrix, wherein the Hermitian matrix is a result of the linear transform.

7. The method of claim 1, wherein the determining comprises using a single parameter depolarization probabilistic bidirectional reflectance distribution function (BRDF).

8. The method of claim 7, wherein the single parameter determines a fractional contribution of specular versus diffuse reflection.

9. The method of claim 7, wherein the single parameter is one of a largest or a unique eigenvalue in a triply degenerate (TD) coherency eigenspectrum.

10. The method of claim 9, comprising compressing one or more Mueller matrices data associated with the one or more depolarizing components into a TD model database that retains dominant polarimetric properties for both diffuse and specular light-matter interactions.

11. The method of claim 10, wherein for each 4×4 Mueller matrix, the TD model database consists of 8 parameters that include a radiometric average throughput, a depolarization parameter, and 6 parameters that describe a dominant coherent process.

12. The method of claim 7, wherein the single parameter is used to determine a probability of a fully polarized or unpolarized light-matter interaction occurrence.

13. A device for tracing rays of light in a system that includes one or more depolarizing components, the device comprising:
a processor; and
a memory including instructions stored thereon, the instructions upon execution by the processor causing the processor to:
generate an incoming polarized ray, wherein the incoming ray is characterized by parameters including a direction, a radiance, and a polarization state;
determine an exitant ray of the system using a probabilistic computation after interaction with the one or more depolarizing components, wherein each depolarizing component is characterized by four Jones matrices and four scalar numeric values associated with probabilities of the four Jones matrices, wherein determination of the exitant ray includes:
selecting a Jones matrix from the four Jones matrices and using the selected Jones matrix and the parameters of the incoming ray to compute a direction and a radiance of the exitant ray after interaction with a material that is at least partially depolarizing; and
repeat the steps of generating an incoming ray and determining an exitant ray one or more times to produce one or more exitant rays until a convergence criterion is reached.

14. The device of claim 13, wherein the instructions upon execution by the processor cause the processor to determine a contribution associated with a partially-polarized light as part of the determination of the exitant ray based on a fractional contribution of fully-polarized versus unpolarized light upon interaction with the one or more depolarizing components that are obtained using one or more polarimetric measurements.

15. The device of claim 13, wherein the selecting the Jones matrix is performed based on the four probability values.

16. The device of claim 13, wherein the convergence criterion includes one of:
completion of tracing a predetermined number of rays, or
upon reaching a condition where a characteristic of an exitant ray remains substantially unchanged compared to one or more previous exitant rays.

17. The device of claim 13, the instructions upon execution by the processor cause the processor to obtain the four scalar numeric values using a linear transform that converts a Mueller matrix associated with the one or more depolarizing components in a Hermitian form.

18. The device of claim 17, wherein the four scalar numeric values are eigenvalues of a Hermitian matrix, wherein the Hermitian matrix is a result of the linear transform.

19. The device of claim 13, wherein the determination of the exitant ray comprises using a single parameter depolarization probabilistic bidirectional reflectance distribution function (BRDF).

20. The device of claim 19, wherein the single parameter determines a fractional contribution of specular versus diffuse reflection.

21. The device of claim 19, wherein the single parameter is one of a largest or a unique eigenvalue in a triply degenerate (TD) coherency eigenspectrum.

22. The device of claim 21, wherein the instructions upon execution by the processor cause the processor to compress one or more Mueller matrices data associated with the one or more depolarizing components into a TD model database that retains dominant polarimetric properties for both diffuse and specular light-matter interactions.

23. The device of claim 22, wherein for each 4×4 Mueller matrix, the TD model database consists of 8 parameters that include a radiometric average throughput, a depolarization parameter, and 6 parameters that describe a dominant coherent process.

24. The device of claim 19, wherein the single parameter is used to determine a probability of a fully polarized or unpolarized light-matter interaction occurrence.
